(19) United States
(12) Patent Application Publication
(10) Pub. No.: US 2026/0282640 A1
(43) Pub. Date: Sep. 17, 2026

(54) METHOD FOR MANUFACTURING LIGHT-EMITTING MODULE, METHOD FOR MANUFACTURING IMAGE DISPLAY DEVICE, AND LIGHT-EMITTING MODULE

(71) Applicant: NICHIA CORPORATION, Anan-shi (JP)

(72) Inventors: Katsuyoshi KADAN, Katsuura-gun (JP); Hajime AKIMOTO, Anan-shi (JP); Norimasa YOSHIDA, Tokushima-shi (JP)

(73) Assignee: NICHIA CORPORATION, Anan-shi (JP)

(21) Appl. No.: 19/680,607

(22) Filed: May 18, 2026

Related U.S. Application Data
(63) Continuation of application No. PCT/JP2024/041873, filed on Nov. 26, 2024.

(30) Foreign Application Priority Data
Nov. 29, 2023 (JP) 2023-202042

(51) Int. Cl. H10H 29/855; H10H 29/01; H10H 29/49

(52) U.S. Cl. CPC H10H 29/8552; H10H 29/012; H10H 29/0363; H10H 29/49

(57) ABSTRACT

A method for manufacturing a light-emitting module according to an embodiment includes: preparing a first intermediate member including a support member having a first surface and a second surface, a wiring layer provided on the first surface, a plurality of light-emitting elements electrically connected to the wiring layer on the first surface, and a photoresist member covering the light-emitting elements; and forming a second intermediate member by lighting the plurality of light-emitting elements to expose a plurality of first portions of the photoresist member to light. The photoresist member is sensitive to irradiation with light including a wavelength of light of the plurality of light-emitting elements.

### CROSS-REFERENCE TO RELATED APPLICATION

This application is a bypass continuation application of International Application No. PCT/JP2024/041873, filed on Nov. 26, 2024, which claims priority to Japanese Patent Application No. 2023-202042, filed on Nov. 29, 2023. The entire disclosures of these applications are hereby incorporated by reference.

### TECHNICAL FIELD

Embodiments relate to a method for manufacturing a light-emitting module, a method for manufacturing an image display device, and a light-emitting module.

### BACKGROUND

Light-emitting modules including a plurality of light-emitting elements arranged in a planar shape are widely used as backlights of liquid crystal displays and various planar light sources. Applications of the light-emitting modules as a self-luminous display are also expected.

In such a light-emitting module, by reducing the size of the light-emitting element, the module can become thinner and lighter.

On the other hand, due to reducing the size of the light-emitting element, a higher light extraction efficiency is desired, and in order to improve the light extraction efficiency, it is necessary to improve the accuracy of forming a light shielding member that is a member for controlling a light distribution of the light-emitting element. As a technique related to the member for controlling the light distribution of the light-emitting element, a light-emitting device is known as including a transparent rectangular parallelepiped pillar having the same planar shape as the light-emitting element, and a lens portion surrounding the pillar (Japanese Patent Publication No. 2016-525288).

### SUMMARY

An object of the embodiments is to provide a method for manufacturing a light-emitting module with improved accuracy of forming a light shielding member or a lens, a method for manufacturing an image display device, and a light-emitting module.

A method for manufacturing a light-emitting module according to an embodiment comprises: preparing a first intermediate member comprising: a support member having a first surface and a second surface opposite the first surface, wiring layer at least partially located on the first surface, a plurality of light-emitting elements, each of which is arranged on a first surface side of the support member, has a light extraction surface through which light is emitted along a direction from the second surface to the first surface, and is electrically connected to the wiring layer, and a first photoresist member integrally covering the plurality of light-emitting elements; and forming a second intermediate member in which a plurality of first portions of the first photoresist member according to an arrangement of the plurality of light-emitting elements have been sensitized to light emitted from the plurality of light-emitting elements by supplying a current to the plurality of light-emitting elements via the wiring layer.

A light-emitting module according to an embodiment comprises: a substrate comprising: a support member having an upper surface, and a wiring layer; a plurality of light-emitting elements, each of which is arranged on an upper surface side of the substrate, has a light extraction surface through which light is emitted upward from the substrate, and is electrically connected to the wiring layer; and a light shielding member containing a photosensitizer and arranged around each of the plurality of light-emitting elements in a top view. The light-emitting module comprises a recessed portion opened upward at a position corresponding to each of the plurality of light-emitting elements, each recessed portion being defined by the light extraction surface of a respective light-emitting element and a lateral surface of the light shielding member.

According to the present embodiment, the method for manufacturing a light-emitting module with improved accuracy of forming a light shielding member or a lens, and the method for manufacturing an image display device can be provided.

### BRIEF DESCRIPTION OF DRAWINGS

FIG. 1 is a schematic top view illustrating a light-emitting module according to a first embodiment.

FIG. 2A is a schematic cross-sectional view taken along a line IIA-IIA in FIG. 1.

FIG. 2B is a schematic cross-sectional view illustrating a light-emitting module according to a modified example of the first embodiment.

FIG. 3 is a schematic cross-sectional view illustrating a step of a method for manufacturing a light-emitting module according to the first embodiment.

FIG. 4 is a schematic cross-sectional view illustrating a step of the method for manufacturing a light-emitting module according to the first embodiment.

FIG. 5 is a schematic cross-sectional view illustrating a step of the method for manufacturing a light-emitting module according to the first embodiment.

FIG. 6 is a schematic perspective view illustrating a step of the method for manufacturing a light-emitting module according to the first embodiment.

FIG. 7A is a schematic cross-sectional view illustrating a step of the method for manufacturing a light-emitting module according to the first embodiment.

FIG. 7B is a schematic cross-sectional view illustrating a step of a manufacturing step of the light-emitting module according to a modified example of the first embodiment.

FIG. 8 is a schematic cross-sectional view illustrating a step of the method for manufacturing a light-emitting module according to the first embodiment.

FIG. 9 is a schematic exploded view illustrating a step of the method for manufacturing an image display device including the light-emitting module according to the first embodiment.

FIG. 10 is a schematic perspective view illustrating a light-emitting module according to a second embodiment.

FIG. 11 is a schematic enlarged view of a portion XI in FIG. 10.

FIG. 12 is a schematic cross-sectional view taken along a line XII-XII in FIG. 10.

FIG. 13 is a schematic enlarged view of a portion XIII in FIG. 12.

FIG. 14 is a schematic cross-sectional view illustrating a step of a method for manufacturing a light-emitting module according to the second embodiment.

FIG. 15 is a schematic cross-sectional view illustrating a step of the method for manufacturing a light-emitting module according to the second embodiment.

FIG. 16 is a schematic cross-sectional view illustrating a step of the method for manufacturing a light-emitting module according to the second embodiment.

FIG. 17 is a schematic cross-sectional view illustrating a step of the method for manufacturing a light-emitting module according to the second embodiment.

FIG. 18 is a schematic cross-sectional view illustrating a step of the method for manufacturing a light-emitting module according to the second embodiment.

FIG. 19 is a schematic cross-sectional view illustrating a step of the method for manufacturing a light-emitting module according to the second embodiment.

FIG. 20 is a schematic cross-sectional view illustrating a step of the method for manufacturing a light-emitting module according to the second embodiment.

FIG. 21 is a schematic cross-sectional view illustrating a step of a modified example of the method for manufacturing a light-emitting module according to the second embodiment.

FIG. 22 is a schematic cross-sectional view illustrating a step of a modified example of the method for manufacturing a light-emitting module according to the second embodiment.

FIG. 23 is a schematic top view illustrating an image display device according to a third embodiment.

FIG. 24 is a schematic block diagram illustrating an equivalent circuit of the image display device according to the third embodiment.

FIG. 25 is a schematic top view illustrating an image display device according to a fourth embodiment.

FIG. 26 is a schematic block diagram illustrating an equivalent circuit of the image display device according to the fourth embodiment.

FIG. 27 is a schematic cross-sectional view illustrating a light-emitting module according to a fifth embodiment.

FIG. 28 is a schematic cross-sectional view illustrating a step of a method for manufacturing a light-emitting module according to a sixth embodiment.

FIG. 29 is a schematic cross-sectional view illustrating a step of the method for manufacturing a light-emitting module according to the sixth embodiment.

FIG. 30 is a schematic cross-sectional view illustrating a step of the method for manufacturing a light-emitting module according to the sixth embodiment.

FIG. 31 is a schematic cross-sectional view illustrating a light-emitting module according to the sixth embodiment.

FIG. 32 is a schematic cross-sectional view illustrating a light-emitting module according to a seventh embodiment.

FIG. 33A is a schematic cross-sectional view illustrating an operation of the light-emitting module according to the seventh embodiment.

FIG. 33B is a schematic cross-sectional view illustrating the operation of the light-emitting module according to the seventh embodiment.

FIG. 34 is a schematic cross-sectional view illustrating a light-emitting module according to an eighth embodiment.

FIG. 35 is a schematic cross-sectional view illustrating a light-emitting module according to a ninth embodiment.

FIG. 36 is a schematic cross-sectional view illustrating a light-emitting module according to a reference example.

FIG. 37 is a schematic top view illustrating an image display device according to a tenth embodiment.

FIG. 38 is an SEM photograph showing a first portion of a photoresist member fabricated in a test example.

### DETAILED DESCRIPTION

Embodiments of the present invention are described below with reference to the drawings.

The drawings are schematic or conceptual, and the relationships between thicknesses and widths of portions, the proportions of sizes between portions, and the like are not necessarily the same as the actual values thereof. In addition, even in the case of representing the same portion, dimensions or ratios may be represented differently depending on the drawings.

Note that, in the specification and the drawings, elements similar to those described in relation to a drawing thereinabove are denoted using like reference characters, and a detailed description is omitted as appropriate.

### First Embodiment

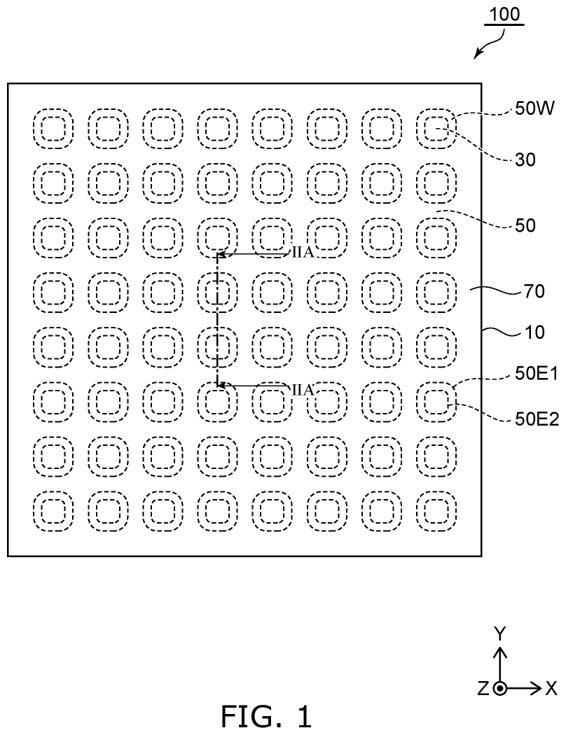

FIG. 1 is a schematic top view illustrating a light-emitting module according to a first embodiment.

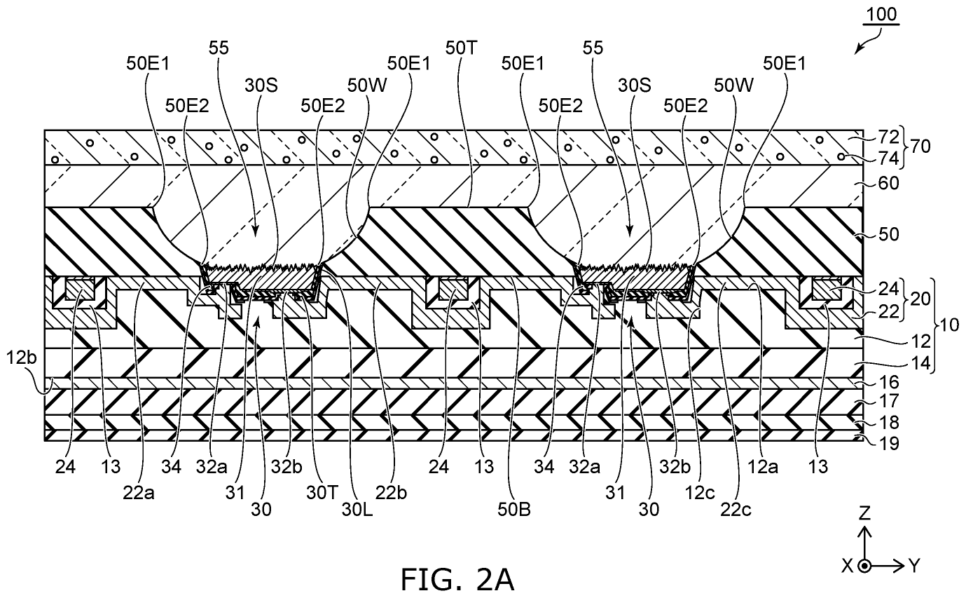

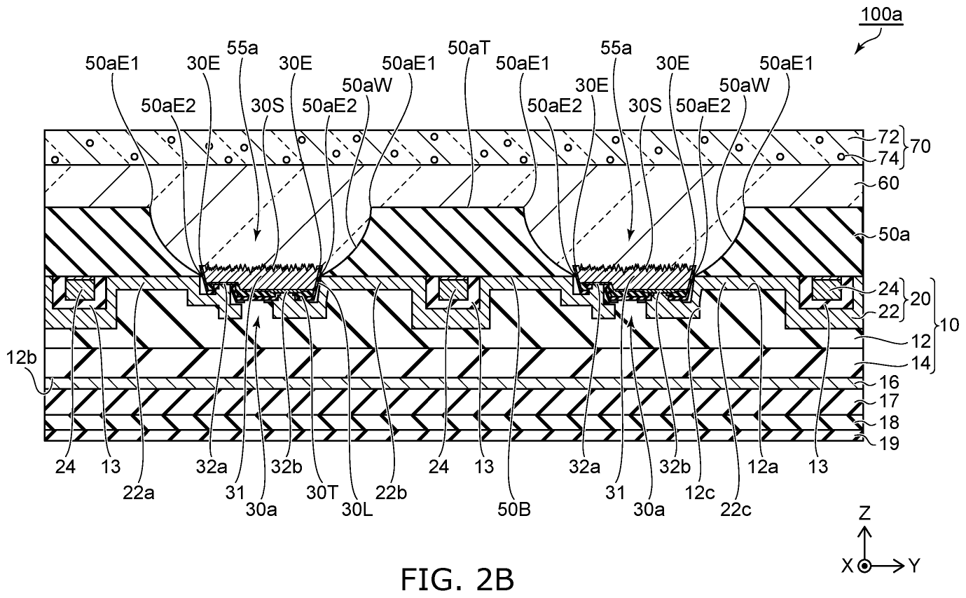

FIG. 2A is a schematic cross-sectional view taken along a line IIA-IIA in FIG. 1.

As illustrated in FIG. 1, a light-emitting module 100 according to the present embodiment includes a substrate 10, a plurality of light-emitting elements 30, a light shielding member 50, and a wavelength conversion member 70. As illustrated in FIG. 2A, the substrate 10 includes a support member 12 and a wiring layer 20. The support member 12 has a first surface 12a. The wiring layer 20 is arranged on the first surface 12a. The plurality of light-emitting elements 30 are arranged on the first surface 12a.

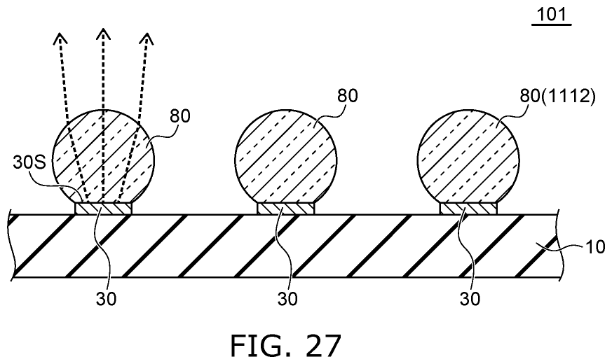

Except for a fifth embodiment illustrated in FIG. 27, in the description of all embodiments and the modified examples thereof, three-dimensional XYZ coordinates may be used. The XY plane is a plane substantially parallel to the first surface 12a. The direction of the X axis is a direction along the row direction of the plurality of light-emitting elements 30 arranged in a matrix. The direction of the Y axis is a direction along the column direction of the plurality of light-emitting elements 30 arranged in a matrix. The Y axis is orthogonal to the X axis. A Z axis is orthogonal to the XY plane. It is assumed that a direction from a second surface 12b located on the opposite side to the first surface 12a of the support member 12 toward the first surface 12a is a positive direction of the Z axis.

The positive direction of the Z axis is sometimes referred to as “up,” “upper,” “upward,” or “upper surface” and the negative direction of the Z axis is sometimes referred to as “down,” “lower,” “downward,” or “lower surface.” The direction along the Z-axis is not necessarily the direction in which gravity is applied. These are intended to facilitate understanding of the description, and are not limited to actual “up,” “upper,” “upward,” “upper surface,” “down,” “lower,” “downward,” or “lower surface.” The length in the Z axis direction may be referred to as “thickness.”

As illustrated in FIG. 1, in the light-emitting module 100, the plurality of light-emitting elements 30 are arranged in a matrix of eight rows× eight columns on the substrate 10 that is substantially square in an XY plane view. The number of rows and the number of columns in which the plurality of light-emitting elements 30 are arranged are not limited to this. For example, the number of rows and the number of columns can be set as necessary according to the application. The arrangement of the plurality of light-emitting elements 30 is not limited to the matrix arrangement as illustrated in FIG. 1, and may be any appropriate arrangement such as a staggered lattice arrangement or a hexagonal lattice arrangement.

In the arrangement of the plurality of light-emitting elements 30 in FIG. 1, the spacing between the adjacent light-emitting elements 30 is the same for all the light-emitting elements 30. The spacing between the adjacent light-emitting elements 30 is not limited to this and may be different depending on the position of the light-emitting element 30 in the light-emitting module 100. For example, in the corner portion of the light-emitting module 100, the number of adjacent light-emitting elements is reduced, and interference due to light between the light-emitting elements is reduced, and thus the luminance is lower than that in the center portion of the light-emitting module 100. Therefore, the spacing between the light-emitting elements 30 may be narrowed in the corner portion of the light-emitting module 100 relative to the spacing between the light-emitting elements 30 in the center portion of the light-emitting module 100, to increase the luminance. The shape of the substrate 10 is not limited to a square, and may be a rectangle, any polygon such as a trapezoid or a rhombus, or a circle depending on the number of the light-emitting elements 30 to be arranged and the mode of arrangement.

As illustrated in FIGS. 1 and 2A, the light shielding member 50 is arranged around each of the plurality of light-emitting elements 30 in a top view. The light-emitting module 100 includes a plurality of recessed portions 55. The plurality of recessed portions 55 are arranged in a matrix in an XY plan view. The plurality of recessed portions 55 are arranged at positions where the plurality of light-emitting elements 30 are arranged, respectively, and are opened upward. The light shielding member 50 penetrates from the bottom of the recessed portion 55 to a lower surface 50B, and the light-emitting elements 30 are arranged in the penetrating holes.

The recessed portion 55 is defined by an inner wall surface 50W and a light extraction surface 30S of the light-emitting element 30 as the bottom surface. The inner wall surface 50W is located between an edge portion 50E1 on an upper surface 50T side and an edge portion 50E2 on the lower surface 50B side of the light shielding member 50. In an XY plan view, the edge portion 50E1 is arranged outside the edge portion 50E2, and an area of a region surrounded by the edge portion 50E1 is larger than an area of a region surrounded by the edge portion 50E2. The light extraction surface 30S of the light-emitting element 30 is exposed from the light shielding member 50 through the edge portion 50E2.

For example, in an XY plan view, the shape of the region surrounded by the edge portion 50E1 is a rectangle with rounded corners. The shape of the region surrounded by the edge portion 50E2 is also the rectangle with rounded corners. For example, the corner portions of the region of the rectangle surrounded by the edge portion 50E1 are more rounded than the corner portions of the region of the rectangle surrounded by the edge portion 50E2.

In an XY plan view, the shapes of the regions surrounded by the edge portion 50E1 and the edge portion 50E2 are not limited to the rectangle with rounded corners. For example, the shape of the region surrounded by the edge portion 50E1 may be substantially a circle or an ellipse, and the shape of the region surrounded by the edge portion 50E2 may be the rectangle with rounded corners. For example, both the shapes of the regions surrounded by the edge portions 50E1 and 50E2 may be the circle or the ellipse. The shapes of the regions surrounded by the edge portions 50E1 and 50E2 can be determined by the shape of the light-emitting element 30 in an XY plan view. For example, when the shape of the light-emitting element 30 in an XY plan view is a polygon having three or more angles, the shapes of the regions surrounded by the edge portions 50E1 and 50E2 in an XY plan view can be a polygon with rounded corners depending on the shape of the polygon of the light-emitting element 30.

In an XY plan view, the edge portion 50E1 is arranged outside the edge portion 50E2, and thus the inner wall surface 50W has a shape of a lateral surface of a frustum widening from the lower surface 50B side toward the upper surface 50T side of the light shielding member 50. In a cross-sectional view, the inner wall surface 50W may linearly widen from the lower surface 50B side toward the upper surface 50T side, or may widen from the lower surface 50B side toward the upper surface 50T side, while forming a recessed surface when viewed from the inside of the recessed portion 55 as illustrated in the specific example in FIG. 2A.

The light shielding member 50 covers a portion of the light-emitting element 30 except for a portion of the light extraction surface 30S of the light-emitting element 30 and the wiring layer 20 on the substrate 10. The light extraction surface 30S is a surface through which light is emitted mainly toward a side of the first surface 12a, and more specifically, a surface through which light is emitted toward the positive direction of the Z axis. Preferably, most of the light extraction surface 30S is exposed from the edge portion 50E2. Thus, the light extraction efficiency of the light-emitting element 30 improves.

The light shielding member 50 contains a material having a light shielding property against light emitted from the light-emitting element 30. Preferably, the light shielding member 50 contains a material having a light reflectivity. For example, the light shielding member 50 contains a light reflective resin. Alternatively, the light shielding member 50 contains light scattering particles such as TiO₂.

When the light shielding member 50 has light reflectivity, light emitted from the light-emitting element 30 is reflected by the inner wall surface 50W and emitted to the outside, and thus the light extraction efficiency of the light-emitting element 30 improves. Further, since the inner wall surface 50W widens from the lower surface 50B side toward the upper surface 50T side of the light shielding member 50, the light emitted from the light extraction surface 30S is emitted while spreading along the inner wall surface 50W. Thus, the light-emitting module 100 can operate as a light source with less luminance unevenness.

The light-reflective resin used for the light shielding member 50 is preferably a thermosetting resin having high heat resistance and light resistance. For example, a silicone resin or an epoxy resin can be suitably used for the light shielding member 50.

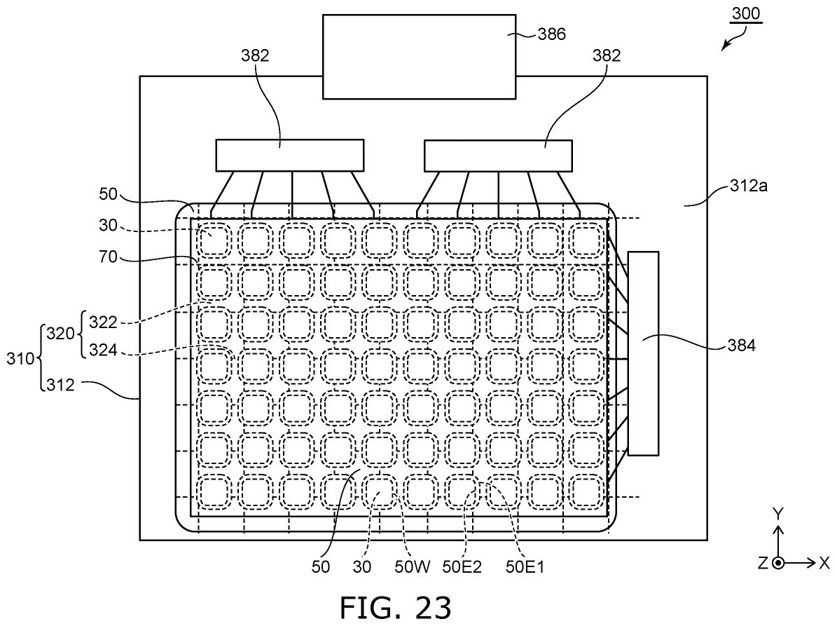

The material contained in the light shielding member 50 is not limited to the material having light reflectivity. Depending on the application of the light-emitting module 100, the light shielding member 50 may be a material that absorbs light. As a material that absorbs light, a resin of a black color can be used. Even a resin colored in black can exhibit light-blocking performance. In image display devices 300 and 400 according to third and fourth embodiments described later in relation to FIGS. 23 to 26, since light emitted from the light-emitting element 30 is less likely to become stray light by using the light shielding member 50 of the black color, a clear image can be displayed.

In the light shielding member 50, the thickness from the upper surface 50T to the lower surface 50B can be, for example, in a range from about 10 μm to about 450 μm. When the light shielding member 50 is made of a light-reflective resin, the light shielding member 50 is preferably thick from a viewpoint of light extraction efficiency.

The light emitted from the plurality of light-emitting elements 30 can be synthesized with each other and emitted. The thickness and material of the light shielding member 50 are set so that the light-emitting module has a planar light source with less luminance unevenness with respect to the light synthesized by the plurality of light-emitting elements 30.

The light-emitting element 30 is arranged on the wiring layer 20. The plurality of light-emitting elements 30 are electrically connected to one another by the wiring layer 20. As illustrated in FIG. 2A, the wiring layer 20 includes a first wiring layer 22 and a second wiring layer 24. The first wiring layer 22 includes a plurality of wirings along the Y direction, and the second wiring layer 24 includes a plurality of wirings along the X direction. The second wiring layer 24 is arranged on the first wiring layer 22 with an insulating layer 13 interposed therebetween. The arrangement of the wirings forming the wiring layer 20 is determined by the circuit configuration of the light-emitting module 100, and is arranged along any direction. The first wiring layer 22 may include wirings along the X direction, and the second wiring layer 24 may include wirings along the Y direction.

By appropriately setting the wiring layer 20, all the light-emitting elements 30 are allowed to emit light at the same time, a plurality of light emitting regions, each of which includes the plurality of light-emitting elements 30, can be provided to switch light emission between the light emitting regions, and the luminance can be controlled for each of the light emitting regions.

The light-emitting element 30 has the light extraction surface 30S and an electrode formation surface 30T. The electrode formation surface 30T is located on the opposite side to the light extraction surface 30S. A pair of electrodes 32a and 32b is arranged on the electrode formation surface 30T. The light-emitting element 30 has a lateral surface 30L. The lateral surface 30L is located between the light extraction surface 30S and the electrode formation surface 30T. The light extraction surface 30S is an upper surface of the light-emitting element 30, and the electrode formation surface 30T is a lower surface of the light-emitting element 30. The wirings forming the wiring layer 20 are connected to the electrodes 32a and 32b of the light-emitting element 30 in a recessed portion 12c arranged on the first surface 12a side of the support member 12.

For example, the electrode 32a is an anode electrode of the light-emitting element 30, and the electrode 32b is a cathode electrode. In the example illustrated in FIG. 2A, the adjacent light-emitting elements 30 are connected in series by the wiring 22b of the first wiring layer 22. Of the two light-emitting elements 30 adjacent to each other, the electrode 32b of the light-emitting element 30 on the positive type side of the Y axis is connected to the wiring 22c, and is electrically connected to, for example, another adjacent light-emitting element. Of the two light-emitting elements 30 adjacent to each other, the electrode 32a of the light-emitting element 30 on the negative side of the Y axis is connected to the wiring 22a, and is electrically connected to, for example, another adjacent light-emitting element.

A shape of the light-emitting element 30 in an XY plan view is, for example, a rectangle. The shape of the light-emitting element 30 in an XY plan view is not limited to the rectangle, and may be a polygon having three or more angles, a circle, or an ellipse. In the case of a polygon, the corner portions may be chamfered or rounded. In this example, a three dimensional shape of the light-emitting element 30 is a truncated pyramid whose diameter increases from the electrode formation surface 30T toward the light extraction surface 30S. The three dimensional shape of the light-emitting element 30 is not limited to the above, and may be a truncated pyramid, a truncated cone, or an elliptical truncated cone whose diameter decreases from the electrode formation surface 30T toward the light extraction surface 30S. The three dimensional shape of the light-emitting element 30 may be a columnar body having the same diameter from the electrode formation surface 30T to the light extraction surface 30S.

A light-reflecting film 34 is preferably arranged on the lateral surface 30L of the light-emitting element 30. The light-reflecting film 34 is, for example, a distributed Bragg reflector (DBR) film. Including the light-reflecting film 34 on the lateral surface 30L suppresses emission of light from the lateral surface 30L and improves the light extraction efficiency of the light-emitting element 30.

The light-emitting element 30 emits light mainly from the light extraction surface 30S. In this example, the light extraction surface 30S is roughened, and the light emitted from the light extraction surface 30S is diffused over a wide range. The light extraction surface 30S is not limited to being roughened and may be a flat surface substantially flattened. Part of the light can be also emitted from the lateral surface 30L and the electrode formation surface 30T.

Each of the light-emitting elements 30 includes a semiconductor structure 31. The electrodes 32a and 32b are connected to a p-type semiconductor layer and an n-type semiconductor layer that form the semiconductor structure 31, respectively. In the semiconductor structure 31, for example, a structure of a light-emitting diode is obtained by layering the p-type semiconductor layer, a light-emitting layer, and the n-type semiconductor layer.

The light-emitting layer may have a structure with a single active layer, such as a double heterostructure or a single quantum well structure (SQW), or may have a structure with a group of active layers, such as a multiple quantum well structure (MQW). The light-emitting layer can emit visible light or ultraviolet light. For example, visible light may include at least blue to red light. An example of the semiconductor structure 31 including such a light-emitting layer can include InₓAl_{y}Ga_{1-x-y}N (0≤x, 0≤y, x+y≤1).

The light-emitting element 30 can include two or more light-emitting layers in the semiconductor structure 31. For example, the semiconductor structure 31 may be a structure including two or more light-emitting layers between the n-type semiconductor layer and the p-type semiconductor layer, or may be a structure in which a layered structure of the n-type semiconductor layer, the light-emitting layer, and the p-type semiconductor layer in sequence is formed repeatedly twice or more. The two or more light-emitting layers may include, for example, light-emitting layers with different light emission colors, or may include light-emitting layers with the same light emission color. The expression “the same light emission color” may include a variation in a range that can be considered as the same light emission color in use. For example, a dominant wavelength of each light emission color may vary by approximately several nanometers. A combination of the light emission colors can be selected as appropriate. For example, when the semiconductor structure includes two light-emitting layers, examples of the combination that can be used include blue light and blue light, green light and green light, red light and red light, ultraviolet light and ultraviolet light, blue light and green light, blue light and red light, and green light and red light.

A light-transmissive member 60 is arranged on the upper surface 50T of the light shielding member 50. The light-transmissive member 60 is arranged on the inner wall surface 50W. The light-transmissive member 60 is arranged on the light-emitting element 30. The light-transmissive member 60 on the light-emitting element 30 covers the light extraction surface 30S exposed from the light shielding member 50 through the edge portion 50E2. The light-transmissive member 60 is provided to provide a substantially flat surface when the wavelength conversion member 70 is arranged on the light-transmissive member 60. The wavelength conversion member 70 may be arranged directly on the light shielding member 50 without the light-transmissive member 60 interposed therebetween, and in this case, the recessed portion 55 is a space filled with air, for example.

The wavelength conversion member 70 is arranged on the light-transmissive member 60. The wavelength conversion member 70 contains a base material 72 having a light-transmissive property and a wavelength conversion substance 74. The wavelength conversion substance 74 converts light emitted from the light-emitting element 30 into light having a different wavelength. Examples of the wavelength conversion substance include quantum dot materials and phosphor materials.

The wavelength conversion member 70 can contain one or a plurality of different types of wavelength conversion substances. In the case of containing a plurality of wavelength conversion substances, for example, the wavelength conversion member 70 can contain a β sialon phosphor that emits green light, and a fluoride-based phosphor such as a KSF-based phosphor that emits red light. Use of the wavelength conversion member 70 containing the plurality of wavelength conversion substances can expand the color reproduction range of the light-emitting module 100.

As the wavelength conversion substance 74, a known phosphor can be used. As the phosphor, an yttrium-aluminum-garnet-based phosphor (for example, Y₃(Al, Ga)₅O₁₂: Ce), a lutetium-aluminum-garnet-based phosphor (for example, Lu₃(Al,Ga)₅O₁₂: Ce), a terbium-aluminum-garnet-based phosphor (for example, Tb₃(Al,Ga)₅O₁₂: Ce), a CCA-based phosphor (for example, Ca₁₀(PO₄)₆C₁₂: Eu), a SAE-based phosphor (for example, Sr₄Al₁₄O₂₅: Eu), a chlorosilicate-based phosphor (for example, CasMgSi₄O₁₆C₁₂: Eu), an oxynitride-based phosphor, a nitride-based phosphor, a fluoride-based phosphor, a phosphor having a perovskite structure (for example, CsPb (F,Cl,Br,I)₃), a quantum dot phosphor (for example, CdSe, InP, AgInS₂, or AgInSe₂), or the like can be used. Typical examples of the oxynitride-based phosphor include β-sialon-based phosphors (for example, (Si,Al)₃(O,N)₄: Eu) and α-sialon-based phosphors (for example, Ca(Si,Al)₁₂(O,N)₁₆: Eu). Typical examples of the nitride-based phosphor include SLA-based phosphors (for example, SrLiAl₃N₄: Eu), CASN-based phosphors (for example, CaAlSiN₃: Eu), and SCASN-based phosphors (for example, (Sr,Ca)AlSiN₃: Eu). Typical examples of the fluoride-based phosphor include KSF-based phosphors (for example, K₂SiF₆: Mn), KSAF-based phosphors (for example, K₂Si_{0.99}Al_{0.01}F_{5.99}: Mn), and MGF-based phosphors (for example, 3.5MgO·0.5MgF₂·GeO₂: Mn).

The base material 72 of the wavelength conversion member 70 is, for example, a sheet-shaped member made of resin. For resin materials for the base material 72, for example, an epoxy resin, a silicone resin, or a resin obtained by mixing the epoxy resin and the silicone resin can be used. Alternatively, as the base material 72, a light-transmissive material such as glass may be used. From the viewpoint of light resistance and ease of molding, a silicone resin is favorably selected as the base material 72. As the wavelength conversion member 70 in which the wavelength conversion substance 74 as described above is dispersed in the base material 72 made of resin, a phosphor sheet can be used.

The support member 12 is preferably formed of a light-reflective resin. The light-reflective resin is, for example, a thermosetting resin having high heat resistance and light resistance. For example, a silicone resin, or an epoxy resin can be suitably used for the light-reflective resin. For example, a member having light reflectivity can be obtained by mixing a light-reflective filler into a silicone resin. The light-reflective filler can be, for example, TiO₂. The thickness of the support member 12 can be in a range from about 15 μm to about 300 μm, for example.

The substrate 10 may include a reinforcing substrate 14. The reinforcing substrate 14 is arranged on the second surface 12b side located on the opposite side to the support member 12 from the first surface 12a. The reinforcing substrate 14 is used to reinforce the mechanical strength of the support member 12. In order to reduce the thickness of the light-emitting module 100, the support member 12 is formed sufficiently thin. If the support member 12 is thin, the support member 12 may be prone to warping or wrinkling. In such cases, it may be difficult to maintain the dimensional accuracy of the light-emitting module 100. Arranging the reinforcing substrate 14 suppresses warping and wrinkling of the support member 12 and reinforces the mechanical strength of the support member 12. As the reinforcing substrate 14, for example, a substrate using a polyimide-impregnated glass cloth can be used. The thickness of the reinforcing substrate 14 can be, for example, in a range from about 25 μm to 200 μm.

In the specific example in FIG. 2A, a plurality of buffer members are arranged below the reinforcing substrate 14. In the buffer member, an adhesion layer 16, a flattening layer 17, an adhesive layer 18, and a buffer layer 19 are arranged in this order from the positive direction toward the negative direction of the Z axis. The buffer member is provided to alleviate thermal stress or mechanical stress applied to the light-emitting module 100 in the manufacturing step or the like. The buffer member may be removed after being used in the manufacturing step.

FIG. 2B is a schematic cross-sectional view illustrating a light-emitting module according to a modified example of the first embodiment.

As illustrated in FIG. 2B, in a light-emitting module 100a, a configuration of a light-emitting element 30a is different from the configuration of the light-emitting element 30 illustrated in FIG. 2A. In the light-emitting module 100a, a configuration of a light shielding member 50a is different from the configuration of the light shielding member 50 illustrated in FIG. 2A. In other respects, the configuration of the light-emitting module 100a is the same as the configuration of the light-emitting module 100 illustrated in FIG. 2A, and the same components are denoted by the same reference characters and detailed description thereof is omitted as appropriate.

In the light-emitting module 100a according to the present modified example, the light-emitting element 30a is not provided with a light-reflecting film on the lateral surface 30L. Thus, the light-emitting element 30a can emit light from the lateral surface 30L.

The light shielding member 50a includes a plurality of recessed portions 55a. The arrangement of the plurality of recessed portions 55a in an XY plan view is the same as or similar to that of the light-emitting module 100 illustrated in FIG. 2A, and thus the detailed description thereof will be omitted.

The recessed portion 55a is defined by an inner wall surface 50aW, the lateral surface 30L of the light-emitting element 30a, and the light extraction surface 30S as the bottom surface.

The inner wall surface 50aW is located between an edge portion 50aE1 on an upper surface 50aT side and an edge portion 50aE2 on the lower surface 50B side of the light shielding member 50a. The inner wall surface 50aW meets the lateral surface 30L of the light-emitting element 30a at the edge portion 50aE2. That is, in the recessed portion 55a, the light extraction surface 30S as the bottom surface is arranged at a position protruding in the positive direction of the Z axis in the recessed portion 55a.

In an XY plan view, the edge portion 50aE1 is arranged outside the edge portion 50aE2 and an edge portion 30E of the light extraction surface 30S. An area of a region surrounded by the edge portion 50aE1 is larger than an area of a region surrounded by the edge portion a50E2 and an area of the light extraction surface 30S.

At least part of light emitted from the lateral surface 30L of the light-emitting element 30a is directed toward the inner wall surface 50aW. When the light shielding member 50a has light reflectivity, the light emitted from the lateral surface 30L of the light-emitting element 30a and directed toward the inner wall surface 50aW is reflected by the inner wall surface 50aW, and at least part of the light is directed upward. The light reflected by the inner wall surface 50aW and directed upward is synthesized with the light emitted from the light extraction surface 30S, and thus the light extraction efficiency of the light-emitting element 30a can be further improved.

### Method for Manufacturing Light-Emitting Module 100

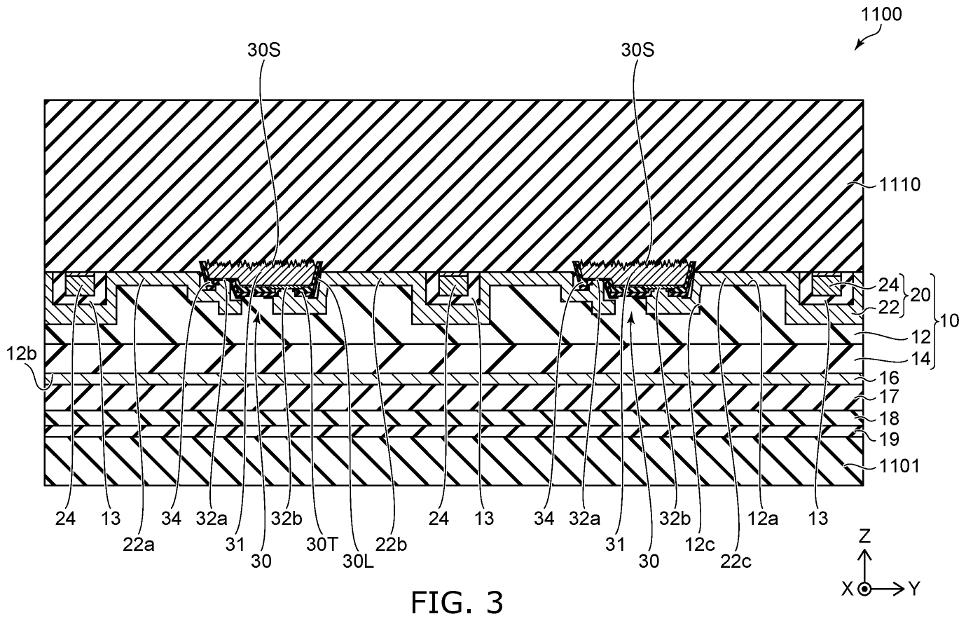

FIGS. 3 to 5, 7A, 7B and 8 are schematic cross-sectional views, each illustrating a step of a method for manufacturing a light-emitting module according to the first embodiment.

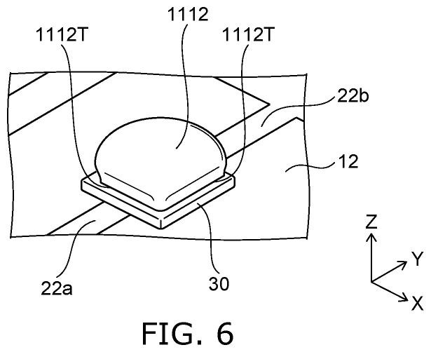

FIG. 6 is a schematic perspective view illustrating a step of the method for manufacturing a light-emitting module according to the first embodiment. FIGS. 3 to 5, 7A, 7B, and 8 are schematic cross-sectional views of a part corresponding to the cross section taken along a line IIA-IIA illustrated in FIG. 1.

As illustrated in FIG. 3, an intermediate member (first intermediate member) 1100 is prepared. The intermediate member 1100 includes the substrate 10, the plurality of light-emitting elements 30, and a photoresist member 1110. The substrate 10 includes the wiring layer 20, the support member 12, and the reinforcing substrate 14.

As described in relation to FIGS. 1 and 2A, the wiring layer 20 is arranged on the first surface 12a side of the support member 12, and the reinforcing substrate 14 is arranged on the second surface 12b side of the support member. The plurality of light-emitting elements 30 are arranged on the first surface 12a side of the support member 12 such that the light extraction surfaces 30S face toward the positive direction of the Z axis, and are electrically connected to the wiring layer 20. The photoresist member 1110 is arranged on the support member 12 and the plurality of light-emitting elements 30, and integrally covers the first surface 12a of the support member 12, the wiring layer 20, and the plurality of light-emitting elements 30. In the intermediate member 1100, the substrate 10 is arranged on the support substrate 1101 through the buffer member including the adhesion layer 16, the flattening layer 17, the adhesive layer 18, and the buffer layer 19. The support substrate 1101 is provided to protect the intermediate member when the intermediate member is moved between steps or during the step.

The photoresist member 1110 is a negative type photoresist. In the negative type photoresist member 1110, the solubility in a developer is reduced at a part irradiated with the light having a predetermined wavelength. In the present embodiment, the wavelength of the light to which the photoresist member 1110 is sensitive includes the wavelength of the light emitted by the light-emitting element 30. When the light-emitting element 30 emits ultraviolet light, a photoresist member 1110 that is sensitive to ultraviolet light can be used. When the photoresist member is sensitive to ultraviolet light, a fine shape can be formed, which is preferable. In addition, when the light-emitting element 30 emits blue light, the photoresist member 1110 that is sensitive to blue light can be used. As described above, as the photoresist member 1110, an appropriate material that is sensitive to light can be used depending on the wavelength of the emitted light of the light-emitting element 30.

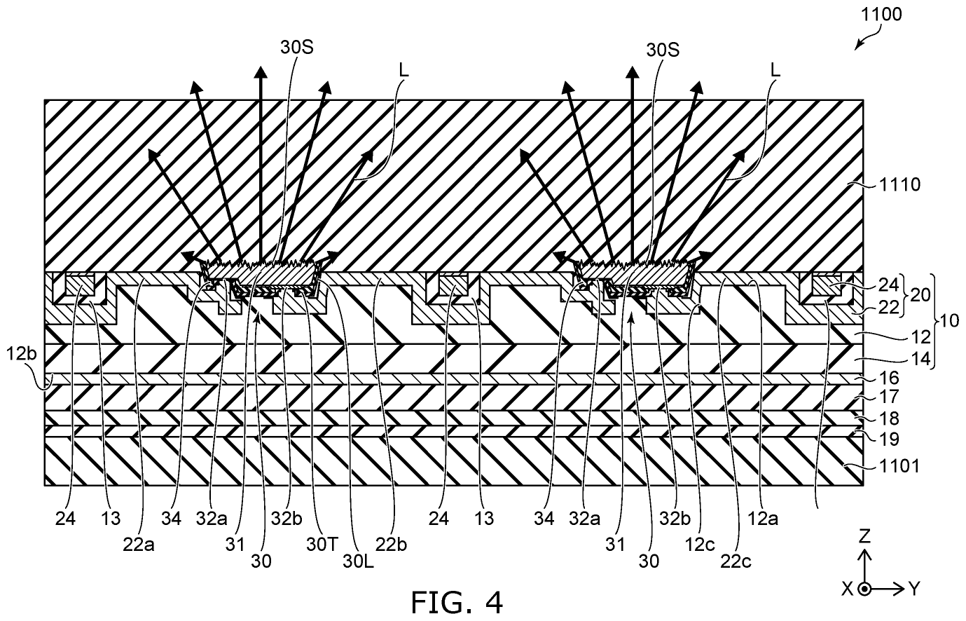

As illustrated in FIG. 4, a current is supplied to the light-emitting element 30 via the first wiring layer 22 to allow the light-emitting element 30 to emit light. As in the example of FIG. 4, the plurality of light-emitting elements 30 may be allowed to emit light at the same time, or the plurality of light-emitting elements 30 may be divided into regions and sequentially allow the regions to emit light, depending on the configuration of the wiring layer 20 including the first wiring layer 22. In the specific example of FIG. 4, two light-emitting elements 30 are connected to each other in series. An external power source circuit is connected to the two light-emitting elements 30 via the wirings 22a and 22c of the first wiring layer 22, and a current is supplied to the two light-emitting elements 30. Accordingly, the two light-emitting elements 30 emit light at the same time.

Light Lis emitted from the light-emitting element 30 according to the light distribution characteristics of the light-emitting element 30. The length of an arrow representing the light L indicates the level of luminance, and the longer the arrow, the higher the luminance. For example, when the light-emitting element 30 has Lambertian light distribution characteristics, as illustrated in FIG. 4, the luminance is highest immediately above the light extraction surface 30S along the optical axis orthogonal to the light extraction surface 30S, and the luminance decreases as the angle from the optical axis increases. The light-exposure amount of the photoresist member 1110 is expressed by the product of the luminance of irradiated light and irradiation time. Thus, the light-exposure amount of the photoresist member 1110 increases immediately above the light extraction surface 30S along the optical axis, and the light-exposure amount decreases as the angle from the optical axis increases.

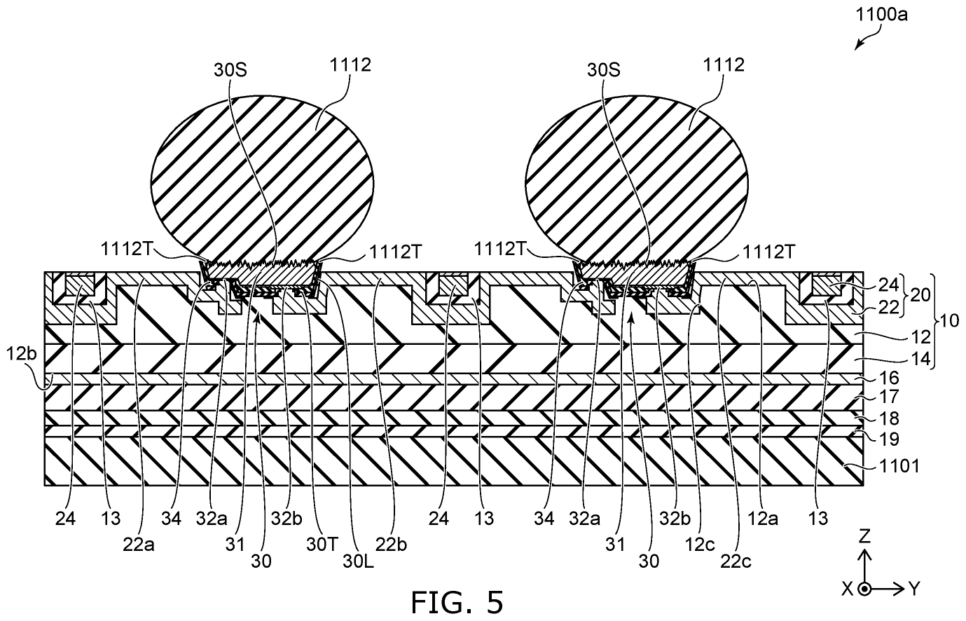

After light-exposure treatment of the photoresist member 1110, in the first intermediate member 1100, a portion of the photoresist member 1110 that is not exposed to light is removed, and a second intermediate member 1100a is formed as illustrated in FIG. 5. In the second intermediate member 1100a, a part of the photoresist member 1110 reaches a predetermined light-exposure amount due to the light emitted by the light-emitting element 30, and a first portion 1112 is formed. The first portion 1112 is formed on the light extraction surface 30S so as to cover a part of the light extraction surface 30S, for each of the light-emitting elements 30. As illustrated in FIGS. 5 and 6, the first portion 1112 is in contact with the light extraction surface 30S at a lower end 1112T of the first portion 1112, and the lower end 1112T covers most of the light extraction surface 30S.

The first portion 1112 is exposed to the light of the light-emitting element 30 and becomes a three dimensional body having surfaces with substantially equal light-exposure amounts. As illustrated in FIG. 6, the first portion 1112 has a shape with rounded corners.

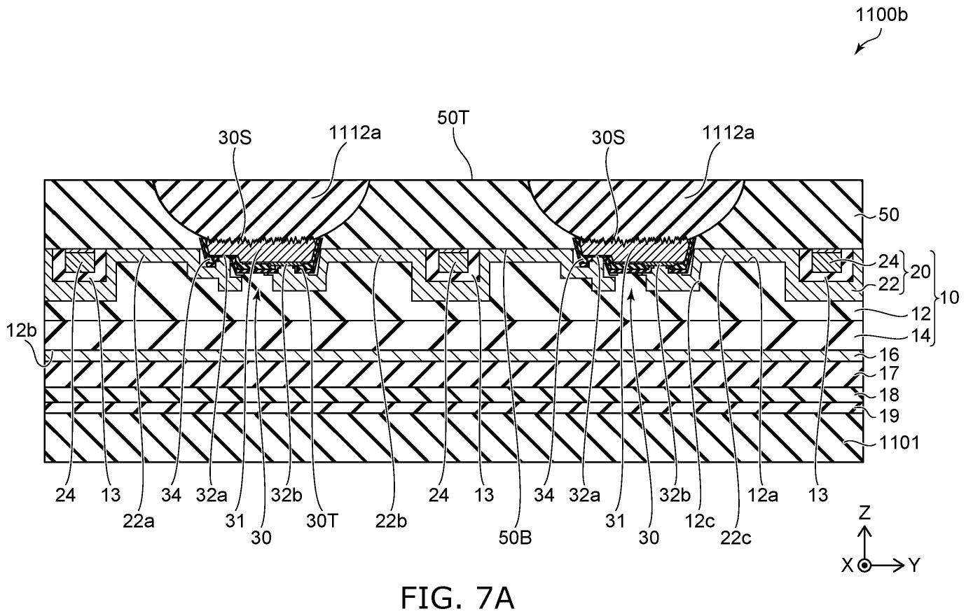

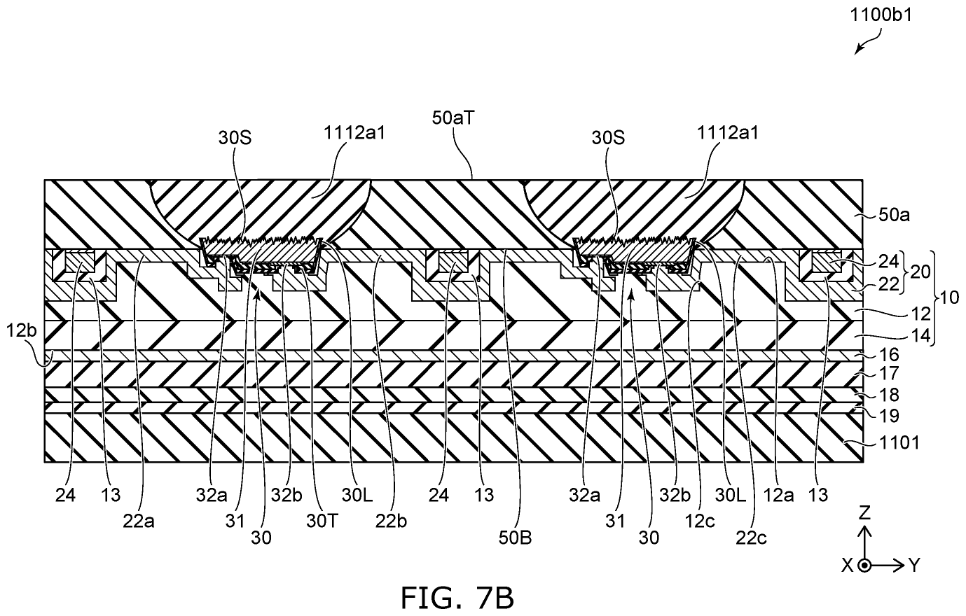

After the second intermediate member 1100a illustrated in FIG. 5 is formed, a thermosetting resin is arranged on the first surface 12a, the wiring layer 20, and a portion of the light-emitting element 30 not covered with the first portion 1112 so as to cover these components. The intermediate member 1100a on which the thermosetting resin has been arranged is subjected to heat treatment to cure the thermosetting resin. Thereafter, the first portion 1112 and the cured thermosetting resin are cut to form the first portion 1112a having been cut and the light shielding member 50 as illustrated in FIG. 7A, thereby forming an intermediate member 1100b.

In the method for manufacturing the light-emitting module 100a according to the modified example illustrated in FIG. 2B, since light is emitted from the lateral surface 30L of the light-emitting element 30a to a lateral side, the photoresist member located on the lateral surface 30L of the light-emitting element 30a is also exposed to light and cured. Thus, as illustrated in FIG. 7B, in an intermediate member 1100b1, a first portion 1112a1 is formed so as to be located on the lateral surface 30L of the light-emitting element 30a.

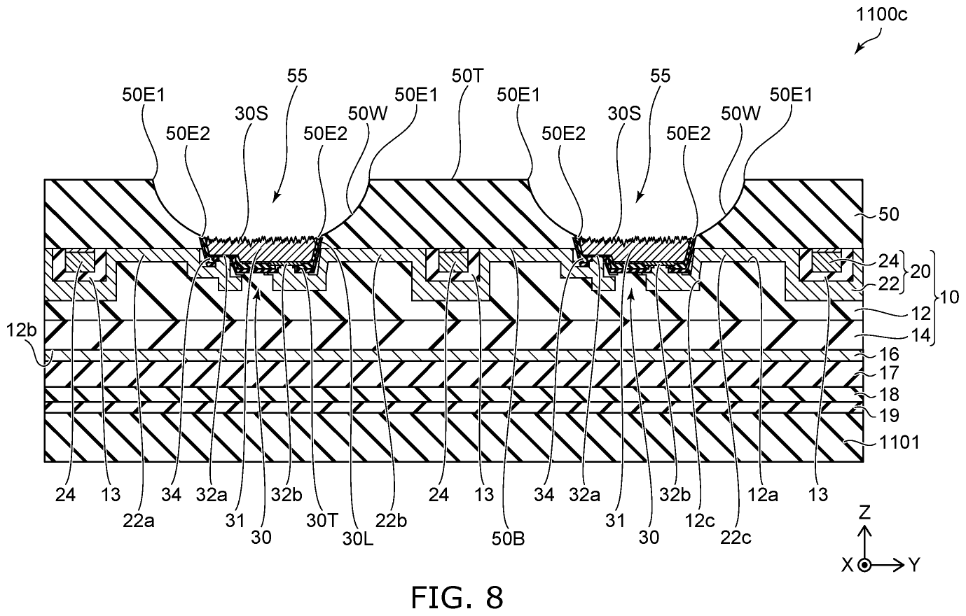

As illustrated in FIG. 8, the first portion 1112a is removed to form the recessed portion 55, and thus an intermediate member 1100c is formed. For example, a reactive ion etching (RIE) can be used for the removal of the first portion 1112a. Similarly to the light-emitting module 100a of the modified example illustrated in FIG. 2B, by removing the first portion 1112a1 illustrated in FIG. 7B, the recessed portion 55a of FIG. 2B can be formed.

After the recessed portion 55 is formed by RIE, the light-transmissive member 60 illustrated in FIG. 2A is arranged on the upper surface 50T of the light shielding member 50, on the inner wall surface 50W, and on the light extraction surface 30S exposed from the light shielding member 50 through the edge portion 50E2, and the wavelength conversion member 70 illustrated in FIG. 2A is arranged on the light-transmissive member 60, thereby forming the light-emitting module 100 illustrated in FIG. 2A. The wavelength conversion member 70 may be arranged on the upper surface 50T and on the recessed portion 55 of the light shielding member 50 of the intermediate member 1100c without arranging the light-transmissive member 60. The support substrate 1101 can also be removed by, for example, laser lift-off.

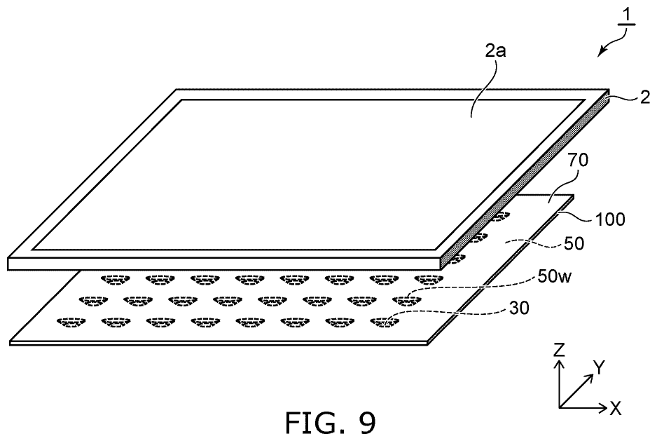

In this way, the light-emitting modules 100 and 100a can be manufactured. FIG. 9 is a schematic exploded view illustrating a step of the method for manufacturing an image display device including the light-emitting module according to the first embodiment.

As illustrated in FIG. 9, the light-emitting module 100 according to the present embodiment described above, and a liquid crystal module 2 are prepared. The light-emitting module 100 is incorporated into the back surface of the liquid crystal module 2, and an image display device 1 is manufactured. The light-emitting module 100 is incorporated on the opposite side to a screen 2a of the liquid crystal module 2, and functions as a backlight for displaying a liquid crystal screen of the liquid crystal module 2 in the image display device 1.

Effects of the method for manufacturing the light-emitting module 100 according to the present embodiment will be described. The same applies to the method for manufacturing the light-emitting module 100a according to the modified example, and the following description will be made using the reference characters and the like related to the method for manufacturing the light-emitting module 100.

In general, in the light-emitting module in which the plurality of light-emitting elements 30 are arranged in a matrix, the area of the opening for exposing the light extraction surface 30S from the light shielding member needs to be sufficiently large in order to improve the light extraction efficiency of the light-emitting element 30.

On the other hand, as illustrated in FIG. 2A, the wirings of the wiring layer 20 are arranged around the light-emitting element 30. When the area of the opening for exposing the light extraction surface 30S from the light shielding member 50 is sufficiently large, the wirings are partially exposed from the light shielding member 50 through the opening. Each of the wirings of the wiring layer 20 includes a metal material such as Cu. When the metal material is irradiated with the light emitted from the light-emitting element 30, at least part of the irradiated light is absorbed by the metal material. Thus, a substantial light extraction efficiency of the light-emitting element 30 decreases.

As described above, in order to improve the light extraction efficiency of the light-emitting element 30, it is necessary to control the formation position and shape of the opening for exposing the light extraction surface 30S from the light shielding member 50 with high accuracy.

In a related art, a step of forming the opening for exposing the light extraction surface 30S from the light shielding member is performed as follows. That is, first, the intermediate member 1100 illustrated in FIG. 3 is prepared, then, at positions aligned with the positions of the plurality of light-emitting elements 30, the photoresist member is exposed to light by an exposure device to form a plurality of masks respectively on the plurality of light-emitting elements.

Then, a thermosetting resin is arranged so as to cover the first surface 12a, the wiring layer 20, and the plurality of light-emitting elements 30, and is cured to form the light shielding member. The plurality of masks are removed by RIE or the like to expose the light extraction surfaces 30S of the plurality of light-emitting elements 30 from the light shielding member 50.

In the case of performing the step of the related art as described above, it is necessary to accurately set the formation position of the mask after accurately measuring the position where the light-emitting element 30 has been arranged. However, the measurement of the position has a restriction on accuracy of a measurement system, and when the variation in the arrangement of the light-emitting elements 30 for each intermediate member is taken into consideration, it is necessary to measure the positions of the light-emitting elements 30 for each intermediate member, and a considerable amount of time is required.

In the method for manufacturing the light-emitting module 100 according to the present embodiment, by preparing the intermediate member 1100 on which the photoresist member 1110 has been arranged so as to cover the light extraction surfaces 30S of the light-emitting elements 30, and allowing the light-emitting elements 30 to emit light for a predetermined time, the photoresist member 1110 is exposed to light. Thus, the intermediate member 1100a in which the first portion 1112 has been formed at the position where the light-emitting element 30 has been arranged can be formed. By using the first portion 1112 as the mask, a thermosetting resin is arranged on the intermediate member 1100a including the first portion 1112 and cured. Thereafter, the cured thermosetting resin is ground together with the first portion 1112 to a desired thickness to remove the first portion 1112a, and thus the recessed portion 55 formed by removing the first portion 1112a can be formed at a position with a reduced deviation from the position where the light-emitting element 30 has been arranged in an XY plan view.

As described above, in the method for manufacturing the light-emitting module 100 according to the present embodiment, the photoresist member 1110 is exposed to light emitted by the light-emitting element 30 and used as a mask for forming the recessed portion 55. Thus, the exposure device is not required, and the manufacturing step of the light-emitting module 100 can be simplified.

Further, since the light-emitting element 30 is allowed to emit light to expose the photoresist member 1110 on the light extraction surface 30S to light, the shape of the lower end 1112T of the first portion 1112 serving as the mask for the recessed portion 55 can be substantially matched with the shape of the light extraction surface 30S in an XY plan view. Thus, most of the region of the light extraction surface 30S can be exposed from the light shielding member 50 through the edge portion 50E2 of the light shielding member 50 formed after the first portion 1112a is removed, and the light extraction efficiency of the light-emitting element 30 can be improved.

A portion of the light-emitting element 30, except for the light extraction surface 30S exposed from the light shielding member 50, is covered with the light shielding member 50, and a metal member, such as the wiring layer 20 on the support member 12, arranged in the vicinity of the light-emitting element 30 can also be covered with the light shielding member 50. Thus, the light emitted from the light extraction surface 30S and directed toward the wiring layer is prevented from being absorbed by the metal material contained in the wirings of the wiring layer, and thus a substantial light extraction efficiency improves.

The cross-sectional shape of the recessed portion 55 is determined depending on the shape of the first portion 1112. The shape of the first portion 1112 is determined depending on the light distribution characteristics of the light-emitting element 30 and the light-exposure amount. Thus, in an XY plan view, an area surrounded by the edge portion 50E1 on the upper surface 50T side of the light shielding member 50 can be increased relative to an area surrounded by the edge portion 50E2 on the lower surface 50B side of the light shielding member 50. Thus, the light can be emitted from the light extraction surface 30S so as to spread along the inner wall surface 50W of the recessed portion 55.

Of the photoresist member 1110, the shape of the first portion 1112 to be sensitive to light can be controlled by the light-exposure amount, which is the product of the luminance of light emitted from the light-emitting element 30 and the light emission time.

For example, the shape of the first portion 1112 can be enlarged by increasing the current value flowing through the light-emitting element 30, increasing the luminance of the light, and increasing the light-exposure amount. Conversely, the shape of the first portion 1112 can be reduced by reducing the current flowing through the light-emitting element 30 to reduce the luminance of the light, and reducing the light-exposure amount.

The light-exposure amount of the photoresist member 1110 can be controlled by the time for irradiating the photoresist member 1110 with light. When the currents flowing through the plurality of light-emitting elements 30 are equalized to uniform the luminance, and the time for irradiating the photoresist member 1110 with light is reduced, the shape of the first portion 1112 can be downsized. When the currents flowing through the plurality of light-emitting elements 30 are equalized to uniform the luminance, and the time for irradiating the photoresist member 1110 with light is increased, the shape of the first portion 1112 can be enlarged.

In one light-emitting module 100, the plurality of light-emitting elements 30 may have variations in characteristics, and even when an equal current flows through the plurality of light-emitting elements 30, the light emitted from the plurality of light-emitting elements 30 may have different luminance. In the method for manufacturing the light-emitting module 100 according to the present embodiment, for example, when an equal current flows through the plurality of light-emitting elements 30 for the same time, the light-emitting element 30 having low luminance results in a small light-exposure amount of the photoresist member 1110, and the light-emitting element 30 with high luminance results in a large light-exposure amount of the photoresist member 1110. When the light-emitting element 30 results in a small light-exposure amount, the first portion 1112 formed by this light-emitting element 30 has a relatively small shape. On the other hand, when the light-emitting element 30 results in a large light-exposure amount, the first portion 1112 has a relatively large shape.

The light-emitting element 30 that emits light with lower luminance emits light through a small recessed portion 55 formed by the first portion 1112 having a small shape. Since the light with low luminance is emitted through a narrow and small recessed portion 55, the decrease in the luminance due to the spread of light is insignificant.

The light-emitting element 30 that emits light with higher luminance emits light through a large recessed portion 55 formed by the first portion 1112 having a large shape. Since the light with high luminance is emitted through a wide and large recessed portion 55, the light spreads, and the luminance decreases due to the spreading.

Thus, when these light-emitting elements 30 are allowed to emit light at the same time with an equal current, the variation in the luminance is relatively reduced, and the in-plane luminance of the light-emitting module 100 as a surface light-emitting device at the time of light emission can become more uniform. This is more effective when the light-emitting module 100 is used as an image display rather than as a backlight.

In the method for manufacturing the light-emitting module 100 according to the present embodiment, the photoresist member 1110 is sensitive to light emitted by the light-emitting element 30, and the first portion 1112 is formed in a self-aligned manner. When the light-emitting element 30 emits light including ultraviolet light, the photoresist member 1110 that is sensitive to ultraviolet light can be used. Since the photoresist sensitive to light having a short wavelength such as ultraviolet light exhibits high processing accuracy, the shape of the first portion 1112 can be more accurately controlled, and the recessed portion 55 can be formed in a desired shape.

### Second Embodiment

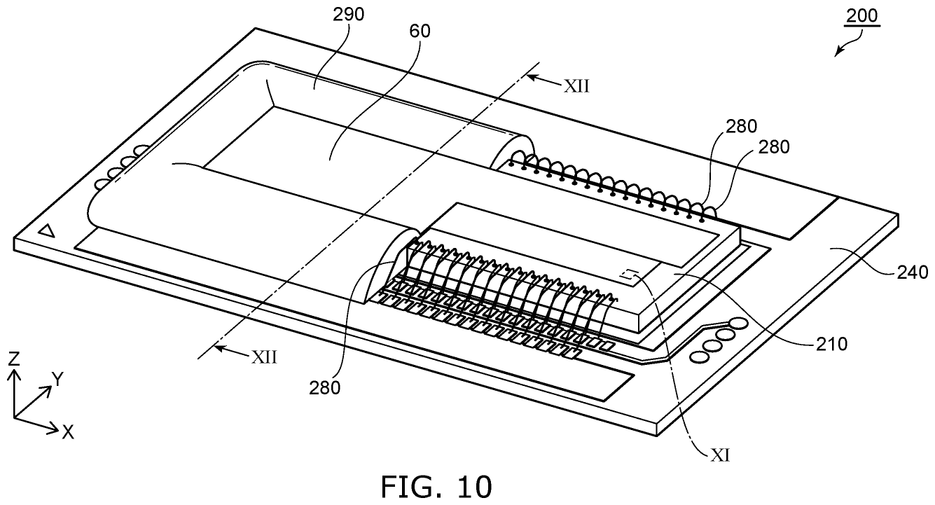

FIG. 10 is a schematic perspective view illustrating a light-emitting module according to a second embodiment.

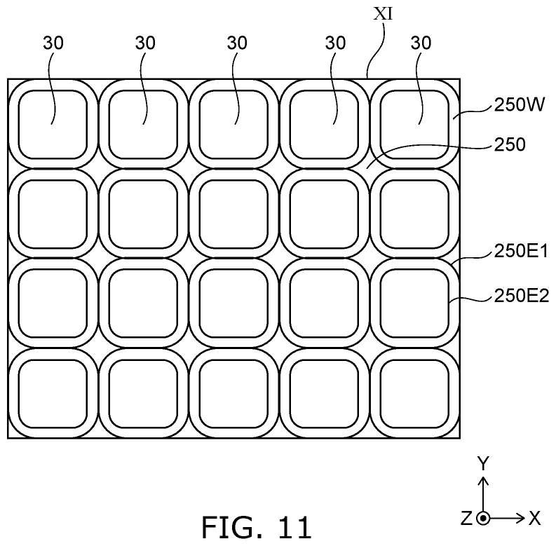

FIG. 11 is a schematic enlarged view of a portion XI in FIG. 10.

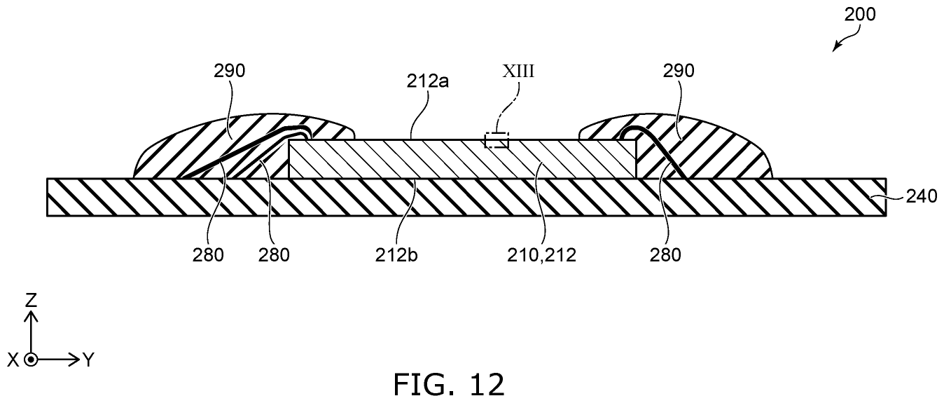

FIG. 12 is a schematic cross-sectional view taken along a line XII-XII in FIG. 10.

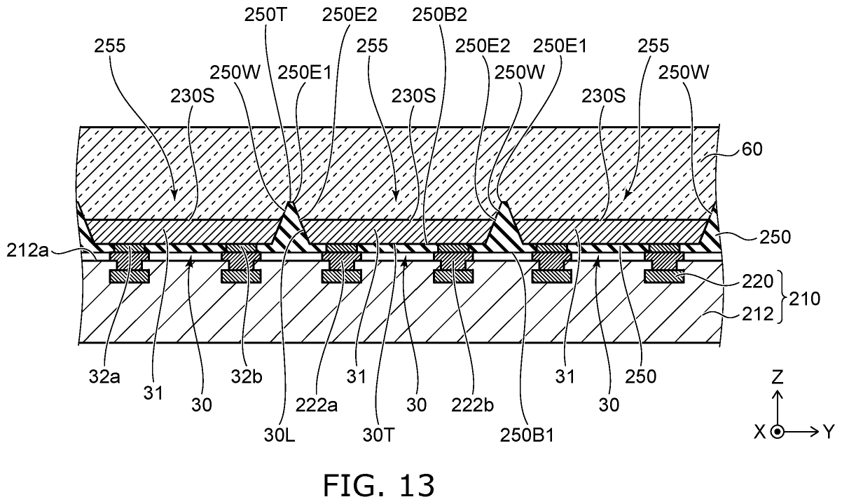

FIG. 13 is a schematic enlarged view of a portion XIII in FIG. 12.

As illustrated in FIGS. 10 to 13, a light-emitting module 200 according to the present embodiment includes a substrate 210, the plurality of light-emitting elements 30, a light shielding member 250, and the light-transmissive member 60. The light-emitting module 200 further includes a package substrate 240, wires 280, and a wire protection member 290. In FIG. 10, in order to more clearly illustrate each component in relation to FIGS. 11 to 13, a state in which a part of the light-transmitting member 60 and a part of the wire protection member 290 have been removed is illustrated. Accordingly, FIG. 10 illustrates some of the wires 280, a part of the substrate 210 under the light-transmissive member 60, and the like.

As illustrated in FIG. 11, in the light-emitting module 200, the plurality of light-emitting elements 30 are arranged in a matrix in an XY plane view. The number of rows and the number of columns in which the plurality of light-emitting elements 30 are arranged can be set as appropriate to any needed number of rows and number of columns according to the application. The arrangement of the plurality of light-emitting elements 30 is not limited to the matrix arrangement, and may be, for example, the staggered lattice arrangement or the hexagonal lattice arrangement, similarly to the first embodiment. In addition, the spacing between the light-emitting elements 30 and the shape of the substrate 210 in an XY plan view can be optionally set as appropriate. The configuration of the plurality of light-emitting elements 30 is the same as or similar to that of the first embodiment, and a detailed description thereof will be omitted.

The light shielding member 250 is arranged around each of the plurality of light-emitting elements 30 in a top view. The light-emitting module 200 includes a recessed portion 255 that is open at a position corresponding to each of the plurality of light-emitting elements 30.

As illustrated in FIG. 13, the light shielding member 250 has an upper surface 250T and a lower surface 250B1 in a cross-sectional view. The recessed portion 255 is defined by an inner wall surface 250W of the light shielding member 250 and the light extraction surface 30S as the bottom surface. The inner wall surface 250W is arranged between the upper surface 250T and the light extraction surface 30S. The light shielding member 250 further has a surface 250B2. The surface 250B2 is located on the opposite side to the lower surface 250B1 corresponding to the position of the recessed portion 255 in an XY plan view. The surface 250B2 is in contact with the electrode formation surface 30T of the light-emitting element 30. In the example illustrated in FIG. 13, in the inner wall surface 250W, the surface 250B2 meets with a surface in contact with the lateral surface 30L of the light-emitting element 30 below the light extraction surface 30S.

The electrode 32a of the light-emitting element 30 penetrates from the surface 250B2 to the lower surface 250B1, together with a connecting member 222a. The electrode 32b of the light-emitting element 30 penetrates from the surface 250B2 to the lower surface 250B1, together with a connecting member 222b. That is, the light shielding member 250 is arranged on an upper surface 212a between the lateral surfaces 30L of two adjacent light-emitting elements, and is also arranged between the electrode formation surface 30T and an upper surface 212a of one light-emitting element 30. When the light shielding member 250 includes a material having light reflectivity, the light shielding member 250 reflects light emitted downward or to the lateral side of the light-emitting elements 30, and the reflected light can be converted into light to be emitted from the light extraction surface 30S, and thus the light extraction efficiency of the light-emitting element 30 improves.

As illustrated in FIGS. 11 and 13, a part of the light extraction surface 30S is exposed from the light shielding member 250 through an edge portion 250E2. Preferably, most of the light extraction surface 30S is exposed from the light shielding member 250 through the edge portion 250E2. Accordingly, the light extraction efficiency of the light-emitting element 30 improves.

In an XY plan view, in the recessed portion 255, an edge portion 250E1 of the inner wall surface 250W on the upper surface 250T side is located outside the edge portion 250E2. An area of a region surrounded by the edge portion 250E1 is larger than an area of a region surrounded by the edge portion 250E2.

For example, in an XY plan view, a shape of the region surrounded by the edge portion 250E1 is a rectangle with rounded corners. A shape of the region surrounded by the edge portion 250E2 is also a rectangle with rounded corners. For example, the corner portions of the region of the rectangle surrounded by the edge portion 250E1 are more rounded than the corner portions of the region of the rectangle surrounded by the edge portion 250E2.

In an XY plan view, the shapes of the regions surrounded by the edge portion 250E1 and the edge portion 250E2 are not limited to the rectangle with rounded corners, and can be determined depending on the shape of the light-emitting element 230 in an XY plan view, similarly to the first embodiment.

In an XY plan view, the edge portion 250E1 is located outside the edge portion 250E2, and thus the inner wall surface 250W has a shape of a lateral surface of a frustum widening from the lower surface 250B1 side toward the upper surface 250T side of the light shielding member 250. The inner wall surface 250W may linearly widen from the edge portion 250E2 toward the edge portion 250E1 as illustrated in the specific example of FIG. 13, or may widen from the edge portion 250E2 toward the edge portion 250E1, while forming a recessed surface when viewed from the inside of the recessed portion 255 as described in the first embodiment.

The light shielding member 250 may contain a material that is the same as or similar to that of the light shielding member 50 in the first embodiment, and for example, a silicone resin or an epoxy resin may be suitably used. As will be described in relation to FIGS. 21 and 22, the light shielding member may contain a photosensitizer for a photoresist.

The substrate 210 includes a support member 212 and a wiring layer 220. As illustrated in FIG. 12, the support member 212 has the upper surface 212a and a lower surface 212b. The lower surface 212b is a surface on the opposite side to the upper surface 212a. As illustrated in FIG. 13, the wiring layer 220 is arranged on the upper surface 212a side in the substrate 210. The connecting members 222a and 222b are arranged on the wiring layer 220. The connecting members 222a and 222b are electrically connected to the wiring layer 220. The connecting members 222a and 222b are arranged so as to correspond to the electrodes 32a and 32b of the light-emitting element 30. The light-emitting element 30 is electrically connected to the wiring layer 220 via the connecting members 222a and 222b.

The substrate 210 is, for example, a semiconductor substrate having an integrated circuit embedded therein. The support member 212 contains, for example, silicon. The substrate 210 is, for example, an application specific integrated circuit (ASIC) substrate. The wiring layer 220 is appropriately configured in the support member 212 depending on the function of the ASIC.

The light-emitting element 30 is arranged on the wiring layer 220 through the connecting members 222a and 222b. The plurality of light-emitting elements 30 are electrically connected to each other by the wiring layer 220. For example, the light-emitting element in a set region emits light at set luminance depending on the function set in the ASIC.

The light-transmissive member 60 is arranged on the light extraction surface 30S, on the upper surface 250T of the light shielding member 250, and on the inner wall surface 250W of the upper portion of the recessed portion 255. As the light-transmissive member 60, a material that is the same as or similar to that in the first embodiment can be used. A wavelength conversion member may be arranged on the light-transmissive member 60, or the wavelength conversion member may be arranged instead of the light-transmissive member 60.

As illustrated in FIGS. 10 and 12, the substrate 210 is arranged on the package substrate 240. The package substrate 240 includes a base having a flat plate shape, and wirings arranged at least on an upper surface of the base. For a material of the base, a material having high heat dissipation is preferably used, and a material having a high light shielding property and strength is more preferably used. Specific examples of the material include a metal such as aluminum (Al) or copper (Cu), a ceramic such as alumina, aluminum nitride, or mullite, a resin such as phenol resin, epoxy resin, polyimide resin, bismaleimide triazine resin (BT resin), or polyphthalamide (PPA), and a composite material made up of a resin and a metal or a ceramic. The package substrate 240 having a flat plate shape may be used, and may include a cavity for housing the substrate 210 on the upper surface. Examples of the material of the wiring include a metal such as copper (Cu), silver (Ag), gold (Au), aluminum (Al), platinum (Pt), titanium (Ti), tungsten (W), palladium (Pd), iron (Fe), and nickel (Ni), and alloys thereof.

As an example, the package substrate 240 is formed by layering an insulating member such as an epoxy resin on the base made of metal such as Al or Cu, and the wirings are arranged on the surface and inside of the package substrate 240. Some of the wirings include a plurality of connection pads on the upper surface of the package substrate 240, and the others of the wirings include a plurality of connection pads on the lower surface of the package substrate 240.

On the upper surface and the lower surface of the package substrate 240, a heat dissipation portion is formed in which the base made of metal is exposed from a base body. The heat dissipation portion is arranged at a substantially center portion of the package substrate 240 in an XY plan view. The connection pads on the upper surface and the lower surface are respectively arranged on both sides of the heat dissipation portion so as to sandwich the heat dissipation portion. The connection pads are arranged along long sides of the package substrate 240, for example.

The wires 280 electrically connect the package substrate 240 and the substrate 210 to each other. The wires 280 are arranged between the connection pad on the upper surface side of the package substrate 240 and the connection pad of the substrate 210, and electrically connect these connection pads to each other. The wire 280 contains a metal material including gold (Au) and having high conductivity.

The wire protection member 290 is arranged so as to cover the wires 280 from the upper surface of the substrate 210 to the upper surface of the package substrate 240. The wire protection member 290 covers the wires 280 to protect the wires 280. The wire protection member 290 may have a light-transmissive property or may have a light shielding property. The wire protection member 290 contains at least a base material made of light transmissive resin, and the base material may contain a light reflective substance or a light absorbing substance. As the base material, a silicone resin or the like can be used.

### Method for Manufacturing Light-Emitting Module 200

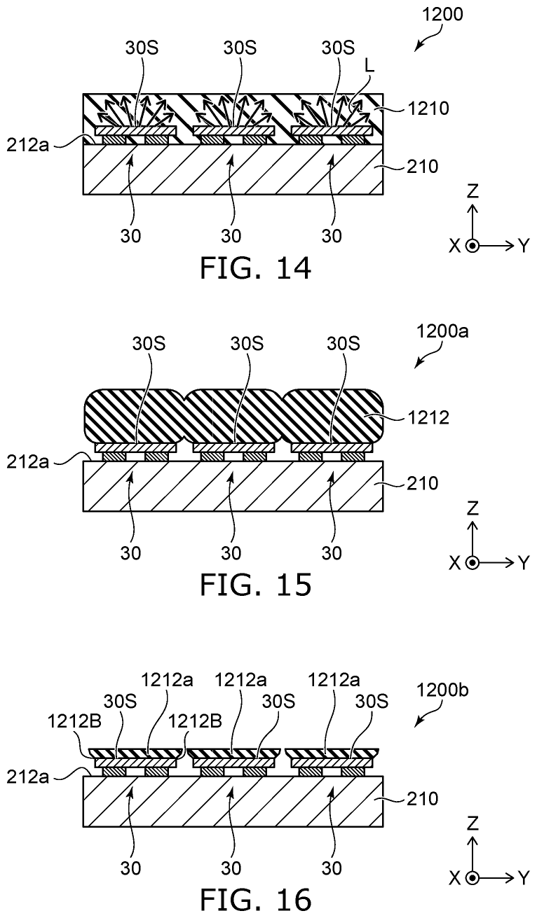

FIGS. 14 to 20 are schematic cross-sectional views, each illustrating a step of a method for manufacturing a light-emitting module according to the second embodiment.

As illustrated in FIG. 14, an intermediate member (first intermediate member) 1200 including the substrate 210, the plurality of light-emitting elements 30, and a photoresist member 1210 is prepared, and a current is supplied to the plurality of light-emitting elements 30 to allow them to emit light, thereby exposing the photoresist member 1210 to light. In the intermediate member 1200, the substrate 210 is the substrate 210 described in relation to FIGS. 10 to 13, and includes the support member 212 and the wiring layer 220. A current is supplied to the plurality of light-emitting elements 30 via the wiring layer 220. In FIGS. 14 to 20, in order to avoid complexity of illustration, in the substrate 210, illustration of the wiring layer 220 and the connecting members 222a and 222b illustrated in FIG. 13 is omitted. The same applies to FIGS. 21 and 22 for describing the modified example of the present method for manufacturing a light-emitting module.

As illustrated in FIG. 14, in the intermediate member 1200, the photoresist member 1210 is arranged on the substrate 210 and the light-emitting elements 30, and integrally covers them. The photoresist member 1210 is a negative type photoresist, and the material that is the same as or similar to that in the first embodiment can be used. The light-emitting element 30 emits light L according to the light distribution characteristics of the light-emitting element 30.

In the intermediate member 1200, a portion of the photoresist member 1210 that is not exposed to light is removed, and an intermediate member 1200a is formed as illustrated in FIG. 15. In the intermediate member 1200a, a part of the photoresist member 1210 reaches a predetermined light-exposure amount due to the light emitted from the light-emitting element 30, and thus a light-exposed portion 1212 is formed, and a portion that is not exposed to light is removed. The light-exposed portion 1212 is formed for each individual light-emitting element 30 in the vicinity of the light-emitting elements 30, and is integrally formed when separated from the light-emitting elements 30 in the positive direction of the Z axis.

An upper portion of the light-exposed portion 1212 of the intermediate member 1200a illustrated in FIG. 15 is removed by polishing or the like, and as illustrated in FIG. 16, an intermediate member 1200b including a plurality of first portions 1212a is formed. The first portion 1212a is in contact with the light extraction surface 30S at a lower end 1212B, and the lower end 1212B covers most of the light extraction surface 30S.

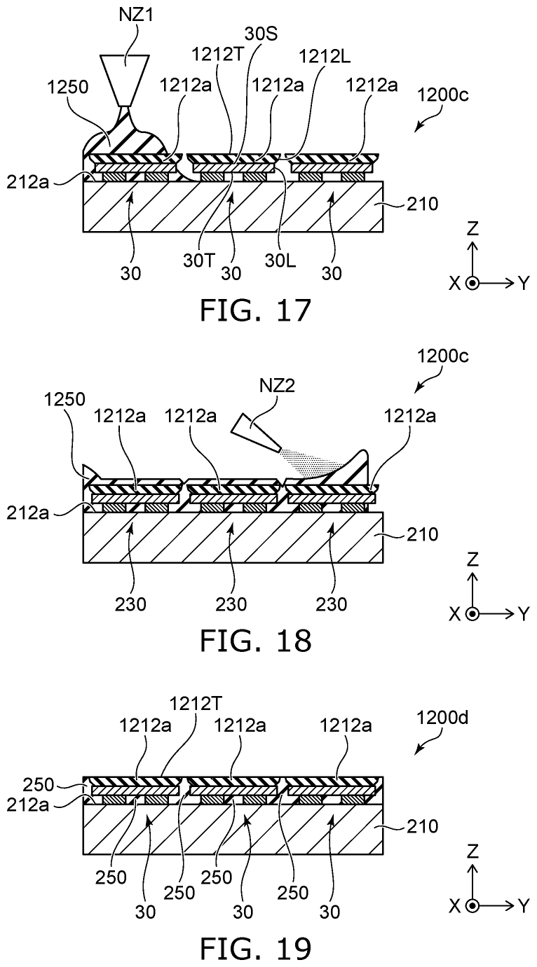

As illustrated in FIG. 17, a nozzle NZ1 for injecting a thermosetting resin 1250 is arranged above the intermediate member 1200b. An intermediate member 1200c is formed by arranging the thermosetting resin 1250 injected from the nozzle NZ1 so as to cover the upper surface (first surface) 212a side of the intermediate member 1200b. More specifically, the thermosetting resin 1250 is arranged on the upper surface 212a. The thermosetting resin 1250 is arranged on a portion of the light-emitting element 30 not covered with the first portion 1212a, the light emitting element 30 including the lateral surface 30L, the electrode formation surface 30T, and the light extraction surface 30S. That is, the thermosetting resin 1250 is arranged between the adjacent light-emitting elements 30 and between the electrode formation surface 30T and the upper surface 212a. The thermosetting resin 1250 is arranged on an upper surface 1212T and a lateral surface 1212L of the first portion 1212a.

As illustrated in FIG. 18, a nozzle NZ2 for ejecting gas such as air is arranged above the intermediate member 1200c. The nozzle NZ2 is arranged with the gas ejection direction inclined from the Z axis, and ejects the gas from obliquely above the thermosetting resin 1250 arranged on the intermediate member 1200c. The upper surface of the thermosetting resin 1250 before being cured is flattened by the gas ejected from the nozzle NZ2. After the thermosetting resin 1250 has become flattened, the intermediate member 1200c is subjected to heat treatment to cure the thermosetting resin 1250.

In the intermediate member 1200c illustrated in FIG. 18, the thermosetting resin 1250 cured on the first portion 1212a is removed by, for example, blasting to expose the upper surface 1212T of the first portion 1212a, thereby forming an intermediate member 1200d illustrated in FIG. 19. As the blasting, for example, dry ice (CO₂) can be used. Since the particles of the dry ice are softer than the semiconductor material constituting the light-emitting element 30, the blasting can be performed without damaging the light-emitting element 30 by spraying the dry ice having a sufficiently small particle size.

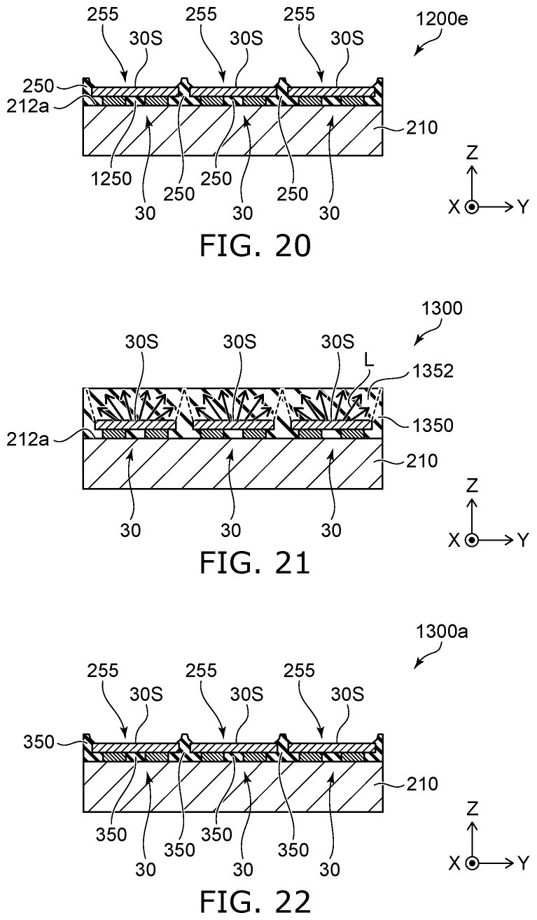

As illustrated in FIG. 20, the first portion 1212a is removed to form a recessed portion 255, thereby forming an intermediate member 1200e. For example, RIE can be used to remove the first portion 1212a.

Then, a wavelength conversion member 70 illustrated in FIG. 13 is arranged on the intermediate member 1200e, and the light-emitting module 200 can be manufactured.

Effects of the method for manufacturing the light-emitting module 200 according to the present embodiment will be described.

The method for manufacturing the light-emitting module 200 according to the present embodiment has the same effects as or similar effects to those of the method for manufacturing the light-emitting module 100 according to the first embodiment. That is, the first portion 1212a is a photoresist member sensitized to light emitted from the light-emitting element 30 and thus having reduced solubility in a developer, and the light shielding member 250 can be formed using the first portion 1212a as a mask. Thus, deviation between the position of the light-emitting element 30 and the formation position of the recessed portion 255 can be reduced. Thus, most of the light extraction surface 30S can be exposed from the light shielding member 250, a portion of the light-emitting element 30, except for the exposed light extraction surface 30S, can be covered with the light shielding member 250, and the light extraction efficiency of the light-emitting element 30 can be improved.

As described above, in the method for manufacturing the light-emitting module 200 according to the present embodiment, the deviation between the position of the light-emitting element 30 and the formation position of the recessed portion 255 can be reduced. Thus, the area of the light extraction surface 30S of the light-emitting element 30 exposed from the light shielding member 250 in the recessed portion 255 can be sufficiently increased. In addition, by reducing the deviation between the position of the light-emitting element 30 and the formation position of the recessed portion 255, the light shielding member 250 having the inner wall surface 250W with a sufficient height can be arranged between the adjacent light-emitting elements 30, 30. Thus, light leakage of the light-emitting element 30 can be reduced, and the light extraction efficiency of the light-emitting element 30 can be improved.

Furthermore, in the method for manufacturing the light-emitting module 200 according to the present embodiment, by reducing the positional deviation between the position of the light-emitting element 30 and the formation position of the recessed portion 255, small light-emitting elements 30 can be arranged on the substrate 210 with high mounting density. Thus, the light-emitting module 200 that ensures sufficient luminance when all the light-emitting elements 30 emit light can be easily manufactured. In addition, by finely controlling the region, the luminance, and the like of the light emitted from the light-emitting element 30, the light-emitting module 200 that can implement various light emission patterns can be easily manufactured.

### Modified Example of Method for Manufacturing Light-Emitting Module 200

FIGS. 21 and 22 are schematic cross-sectional views, each illustrating a step of a modified example of the method for manufacturing a light-emitting module according to the second embodiment.

In the present modified example, a light shielding member is formed using a positive type photoresist member instead of the negative type photoresist member. A light shielding member 350 of the light-emitting module manufactured by the method for manufacturing a light-emitting module in the present modified example contains a photosensitizer for a photoresist. Preferably, the photoresist member may contain a light scattering member that scatters light, and may contain a light absorbing member depending on the application of the light-emitting module 200.

As illustrated in FIG. 21, an intermediate member 1300 is prepared, and a current is supplied to the plurality of light-emitting elements 30 to allow them to emit light, thereby sensitizing a photoresist member 1350 to the light. In the intermediate member 1300, the photoresist member 1350 integrally covers the upper surface 212a of the support member and the plurality of light-emitting elements 30.

A first portion 1352 of the photoresist member 1350 located above the light extraction surface 30S is sensitized to the light emitted from the light-emitting element 30 depending on the light distribution characteristics of the light-emitting element 30. In the positive type photoresist member 1350, the solubility in the developer is increased in a portion that is irradiated with light for a predetermined time and reaches a predetermined light-exposure amount. Thus, the solubility in the developer is increased at the first portion 1352 of the photoresist member 1350.

As illustrated in FIG. 22, the portion that has reached the predetermined light-exposure amount of the light from the light-emitting element 30 is removed, a part of the light extraction surface 30S is exposed, and the recessed portion 255 is formed, thereby forming an intermediate member 1300a.

Thereafter, by arranging the light-transmissive member 60 on the light shielding member 350 and on the light extraction surface 30S of the intermediate member 1300a, the light-emitting module 200 can be manufactured.

In the intermediate member 1300, as the photoresist member 1350, a chemically amplified type photoresist may be used. When the photoresist member 1350 is the chemically amplified type photoresist, a step of subjecting the intermediate member 1300 to heat treatment is added after the intermediate member 1300 illustrated in FIG. 21 has been sensitized to the light of the light-emitting element 30, and then the first portion 1352 exposed to the light is removed.

The chemically amplified type photoresist contains a photoacid generator. The solubility is increased by an acid generated by light exposure. By adding the heat treatment, the acid is further generated, and the solubility at the light-exposed portion is further increased. Thus, the chemically amplified photoresist enables a fine pattern to be formed, and is applied to the present modified example, so that the shape of the first portion 1352 can be more accurately controlled, and the recessed portion 255 can be more accurately formed.

According to the present modified example, by using the positive type photoresist member 1350, the steps of arranging and flattening the thermosetting resin illustrated in FIG. 17 and then removing the cured photoresist member can be shortened to a single step of removing the photoresist member. This can achieve step shortening, cost reduction, and the like.

Further, the photoresist member 1350 can use the chemically amplified type photoresist, and thus the recessed portion 255 can be accurately formed. Thus, the spacing between the light-emitting elements 30 to be arranged can be reduced, and the light-emitting module 200 to which the smaller light-emitting elements 30 are applied can be manufactured.

As in the modified example of the method for manufacturing the light-emitting module 200 illustrated in FIGS. 21 and 22, the light shielding member may be formed using the positive type photoresist member instead of the negative type photoresist member. In each of the methods for manufacturing the light-emitting module 100 according to the first embodiment described in relation to FIGS. 3 to 8, and the light-emitting module 100a according to the modified example of the light-emitting module 100, the photoresist member can be changed from the negative type to the positive type. That is, in the methods for manufacturing the light-emitting modules 100 and 100a, by changing the photoresist member from the negative type to the positive type, the photoresist member after being exposed to light can be used as the light shielding member. Accordingly, the same effects as or similar effects to those of the method for manufacturing the light-emitting module 200 according to the second embodiment can also be obtained.

### Third Embodiment

FIG. 23 is a schematic top view illustrating an image display device according to a third embodiment.

As illustrated in FIG. 23, the image display device 300 includes a substrate 310, the plurality of light-emitting elements 30, the light shielding member 50, and the wavelength conversion member 70. In the present embodiment, the configuration of the substrate 310 is different from that of the first embodiment, and the other configurations are the same as or similar to the light-emitting module 100 according to the first embodiment. The same components are denoted by the same reference characters, and detailed description thereof will be omitted as appropriate.

The plurality of light-emitting elements 30, the light shielding member 50, and the wavelength conversion member 70 are configured similarly to the first embodiment. That is, as illustrated in FIG. 2A and the like, the plurality of light-emitting elements 30 are arranged respectively in the plurality of recessed portions 55 of the light shielding member 50 arranged in a matrix. The wavelength conversion member 70 is arranged on the plurality of light-emitting elements 30 and on the light shielding member 50.

The substrate 310 includes a support member 312 and a wiring layer 320. As the support member 312, for example, a material that is the same as or similar to that of the first embodiment can be used. The substrate 310 further includes current signal drive circuits 382, a row selection drive circuit 384, and a connector 386 for external circuit connection. For example, the wiring layer 320 includes a first wiring layer 322 and a second wiring layer 324, the first wiring layer 322 is electrically connected to the current signal drive circuit 382, and the second wiring layer 324 is electrically connected to the row selection drive circuit 384. The current signal drive circuit 382 and the row selection drive circuit 384 are electrically connected to the connector 386 for external circuit connection, and are electrically connected to, for example, an image display control circuit provided outside the image display device 300, via the connector 386 for external circuit connection. The image display device 300 according to the present embodiment displays an image controlled by the image display control circuit, for example.

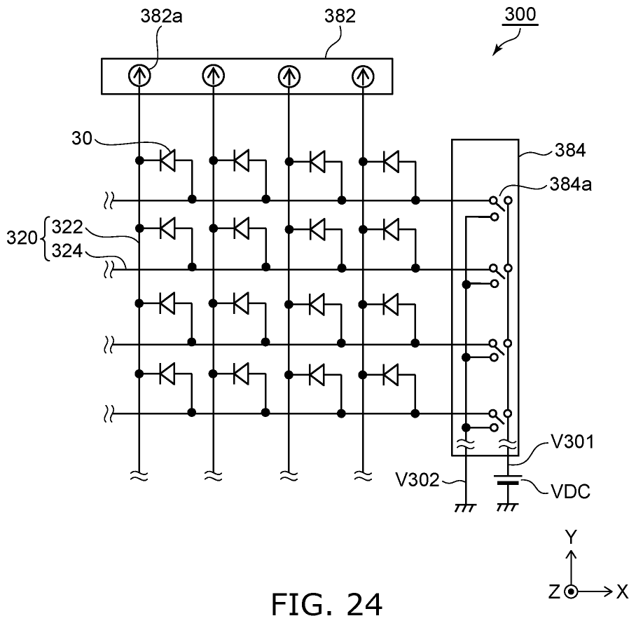

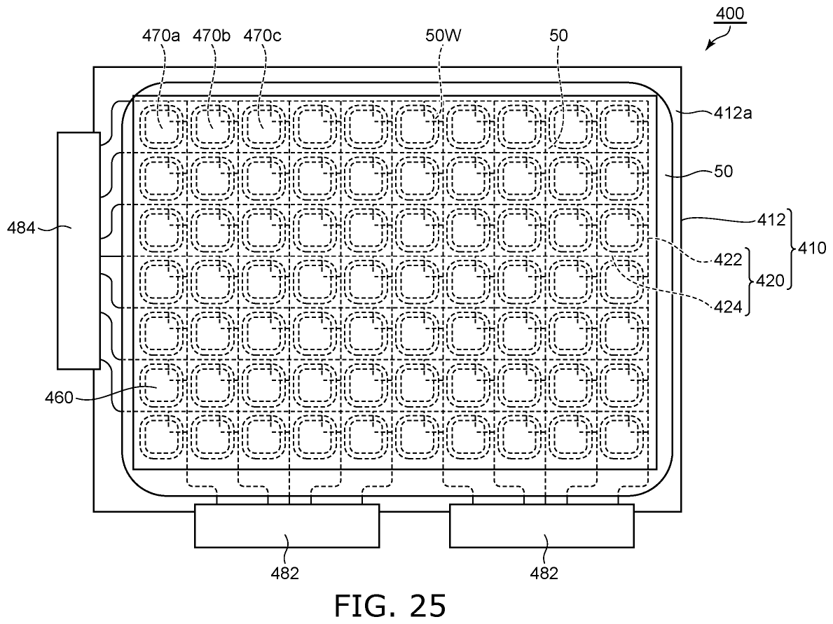

FIG. 24 is a schematic block diagram illustrating an equivalent circuit of the image display device according to the third embodiment.

As illustrated in FIG. 24, in the image display device 300 according to the present embodiment, the light-emitting element 30 is electrically connected to the wiring of the first wiring layer 322 and the wiring of the second wiring layer 324.

The current signal drive circuit 382 includes current sources 382a. The current source 382a is electrically connected to the cathode electrode of the light-emitting element 30 via the first wiring layer 322, for example. A current value output from the current source 382a is set by, for example, the image display control circuit provided outside the image display device 300. The light-emitting element 30 emits light with the luminance depending on the current value.

The row selection drive circuit 384 includes selector switches 384a. Power source lines V301 and V302 are connected to the row selection drive circuit 384. The power source line V302 is connected to a negative electrode of a DC power source VDC. The potential of the power source line V302 is, for example, the ground potential, that is 0 V. The power source line V301 is connected to a positive electrode of the DC power source VDC. The potential of the power source line V301 is higher than the ground potential. The selector switch 384a is connected to, for example, the anode electrode of the light-emitting element 30 via the wiring of the second wiring layer 324. The selector switch 384a connects the anode electrode to the power source line V301 or the power source line V302 by switching therebetween. The DC power source VDC is set to output a voltage sufficiently higher than a threshold value of the light-emitting element 30. When the anode electrode of the light-emitting element 30 is connected to the power source line V301 by the selector switch 384a, a current flows through the light-emitting element 30 to emit light. When the anode electrode of the light-emitting element 30 is connected to the power source line V302 by the selector switch 384a, the current of the light-emitting element 30 is cut off.

For example, the image display device 300 can operate as follows. That is, the current values flowing through the light-emitting elements 30 arranged along the Y axis direction are set by the current source 382a of the current signal drive circuit 382, and the luminance of the light-emitting elements 30 when they are lit is set. Which row of the light-emitting elements 30 arranged along the X axis direction is selected is changed by the selector switch 384a to select the presence or absence of light emission. Thus, the image display device 300 can display a desired image.

The image display device 300 can be manufactured similarly to the method for manufacturing the light-emitting module 100 according to the first embodiment. That is, an intermediate member including the substrate 310, the plurality of light-emitting elements 30, and the photoresist member is prepared. As the photoresist member, the photoresist that is the same as or similar to the photoresist member 1110 illustrated in FIG. 3 can be used. Thereafter, in the intermediate member, similarly to the case illustrated in FIGS. 4 to 8, the photoresist member is exposed to the light emitted by the light-emitting element 30, the first portion is formed, the thermosetting resin is arranged, and the first portion is removed, thereby forming the recessed portion. Thereafter, the wavelength conversion member 70 is arranged. A light-transmissive member may be arranged between the wavelength conversion member 70 and the light shielding member 50, and between the wavelength conversion member 70 and the light-emitting elements 30.

The current signal drive circuit 382, the row selection drive circuit 384, and the connector 386 for external circuit connection are arranged on a first surface 312a of the support member 312, and are electrically connected to the light-emitting elements 30 via the wiring layer 320. For example, the image display device 300 on which the current signal drive circuit 382, the row selection drive circuit 384, and the connector 386 for external circuit connection are mounted is housed in a housing.

In this way, the image display device 300 as the image display device can be manufactured.

### Fourth Embodiment

FIG. 25 is a schematic top view illustrating an image display device according to a fourth embodiment.

As illustrated in FIG. 25, the image display device 400 includes a substrate 410, the plurality of light-emitting elements 30, the light shielding member 50, wavelength conversion members 470a, 470b, and 470c, and a light-transmissive member 460. In the present embodiment, the configuration of the substrate 410 and the configurations of the wavelength conversion members 470a, 470b, and 470c and the light-transmissive member 460 are different from those in the case of the light-emitting module 100 according to the first embodiment, and the other configurations are similar to the first embodiment. The same components are denoted by the same reference signs, and detailed description thereof will be omitted as appropriate.

The plurality of light-emitting elements 30 and the light shielding member 50 are configured similarly to the first embodiment. That is, as illustrated in FIG. 2A and the like, the plurality of light-emitting elements 30 are arranged respectively in the plurality of recessed portions 55 of the light shielding member 50 arranged in a matrix.

The substrate 410 includes a support member 412 and a wiring layer 420. As the support member 412, for example, glass can be used. The substrate 410 further includes a current signal drive circuit 482 and a row selection drive circuit 484. The current signal drive circuit 482 and the row selection drive circuit 484 are, for example, mounted by TAB on the support member 412, and the current signal drive circuit 482 and row selection drive circuit 484 mounted by TAB are electrically connected to an external image display control circuit. The image display device 400 according to the present embodiment displays an image controlled by the image display control circuit, for example.

Each of the wavelength conversion members 470a, 470b, and 470c is arranged on a corresponding one of the light-emitting elements 30. For example, the wavelength conversion member 470a is arranged on one light-emitting element 30, the wavelength conversion member 470b is arranged on the adjacent light-emitting element 30, and the wavelength conversion member 470c is arranged on the adjacent light-emitting element 30. Each of the wavelength conversion members 470a, 470b, and 470c includes a base material and a different type of wavelength conversion substance from the other wavelength conversion substances. The wavelength conversion substance is dispersed in the base material and converts the wavelength of the light emitted by the light-emitting element 30 into light having a predetermined wavelength. For example, all the light-emitting elements 30 emit ultraviolet light of the same wavelength. The wavelength conversion substance contained in the wavelength conversion member 470a converts ultraviolet light into red light. The wavelength conversion substance contained in the wavelength conversion member 470b converts ultraviolet light into green light. The wavelength conversion substance contained in the wavelength conversion member 470c converts ultraviolet light into blue light.

Accordingly, one light-emitting element 30 and the wavelength conversion member 470a arranged thereon constitute a sub-pixel that emits red light. Another one light-emitting element 30 and the wavelength conversion member 470b arranged thereon constitute a sub-pixel that emits green light. Still another one light-emitting element 30 and the wavelength conversion member 470c arranged thereon constitute a sub-pixel that emits blue light. A common light-transmissive member 460 is arranged on a plurality of the wavelength conversion members 470a, 470b, and 470c.

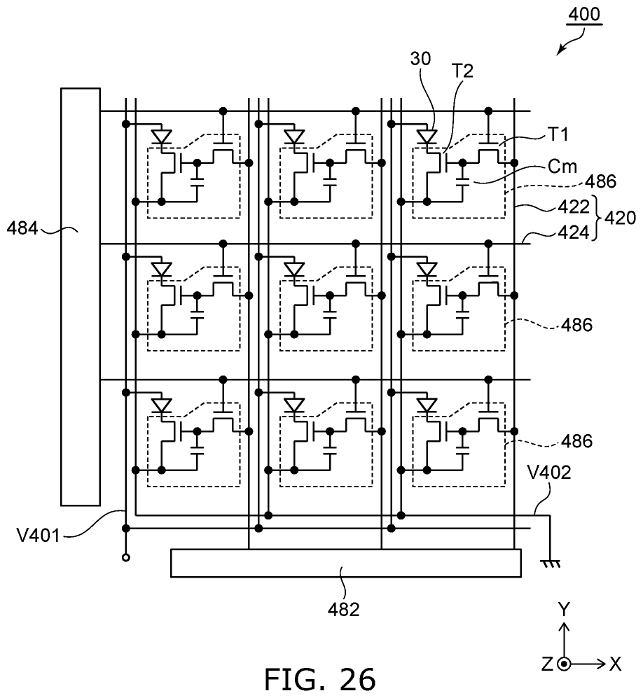

FIG. 26 is a schematic block diagram illustrating an equivalent circuit of the image display device according to the fourth embodiment.

As illustrated in FIG. 26, the image display device 400 includes a plurality of drive circuits 486 that allow the plurality of light-emitting elements 30 to emit light at desired luminance and a desired timing.

For example, the drive circuit 486 includes a selection transistor T1, a drive transistor T2, and a capacitor Cm. The drive transistor T2 is connected in series to the light-emitting element 30. The series circuit of the light-emitting element 30 and the drive transistor T2 is connected between power source lines V401 and V402. The power source lines V401 and V402 are not illustrated in FIG. 25 in order to avoid complexity of illustration. The selection transistor T1 is connected between the wiring forming the first wiring layer 422 and a gate electrode of the drive transistor T2. A gate electrode of the selection transistor T1 is connected to the wiring forming the second wiring layer 424. The capacitor Cm is connected between the gate electrode and a source electrode of the drive transistor T2.

The drive circuit 486 including the selection transistor T1, the drive transistor T2, and the capacitor is arranged on the support member 412, and is electrically connected by the wiring layer. The light-emitting element 30 is arranged on the support member 412 similarly to the drive circuit and electrically connected to the drive circuit. The light-emitting element 30 and the drive circuit may be disposed in different layers on the substrate 410. For example, an interlayer insulating film is arranged on the drive circuit, and the light-emitting element 30 is arranged on the interlayer insulating film. The drive circuit and the light-emitting element are electrically connected to each other via a connecting member penetrating the interlayer insulating film. The selection transistor T1 and the drive transistor T2 are thin film transistors (TFTs), and the drive circuit including the TFTs can be formed by a low-temperature polysilicon process technology.

In the specific example of FIG. 26, one sub-pixel includes one light-emitting element 30, the drive circuit 486 connected to the light-emitting element 30, and the wavelength conversion members 470a, 470b, and 470c arranged on the light-emitting element 30 illustrated in FIG. 25. One pixel is composed of three sub-pixels that emit red, green, and blue light, respectively. The drive transistor T2 drives the light-emitting element 30 with a current depending on a voltage value set by the current signal drive circuit 482. The selection transistor T1 selected by a selection signal output from the row selection drive circuit 484 is turned on to drive the drive transistor T2. The image display device 400 can display a desired image by appropriately setting the luminance of the three sub-pixels that emit three colors and sequentially selecting the sub-pixels by the image display control circuit provided externally.

The image display device 400 can be manufactured similarly to the method for manufacturing the light-emitting module 100 according to the first embodiment. That is, an intermediate member including the substrate 410, the plurality of light-emitting elements 30, and the photoresist member is prepared. The substrate 410 includes a drive circuit that drives the light-emitting elements 30 in addition to the plurality of light-emitting elements 30. As a photoresist-portion member, the photoresist that is the same as or similar to the photoresist member 1110 illustrated in FIG. 3 can be used. Thereafter, in the intermediate member, similarly to the case illustrated in FIGS. 4 to 8, the photoresist member is exposed to the light emitted by the light-emitting element 30, the first portion is formed, the thermosetting resin is arranged, and the first portion is removed, thereby forming the recessed portion. Thereafter, the wavelength conversion member is arranged. A light-transmissive member may be arranged between the wavelength conversion member and the light shielding member 50, and between the wavelength conversion member and the light-emitting elements 30. In order to improve the color development of each pixel, a color filter may be arranged on the wavelength conversion member.

The current signal drive circuit 482, and the row selection drive circuit 484 are arranged on the first surface 412a of the support member 412, and are electrically connected to the light-emitting elements 30 via the wiring layer 420. For example, the image display device 400 on which the current signal drive circuit 482 and the row selection drive circuit 384 are mounted is housed in a housing.

In this way, the image display device 400 that can display a color image can be manufactured.

### Fifth Embodiment

A fifth embodiment is an example in which the first portion 1112 of the photoresist member 1110 illustrated in FIG. 5, the first portion 1112 having been exposed to light, is used as a microlens in a final product in the method for manufacturing a light-emitting module according to the first embodiment.

A method for manufacturing a light-emitting module according to the present embodiment will be described.

First, the steps illustrated in FIGS. 3 to 5 are performed. Accordingly, as illustrated in FIGS. 5 and 6, the first portion 1112 is formed on each light-emitting element 30. The first portion 1112 has a light-transmissive property and has a shape depending on the light distribution characteristics of the light-emitting element 30. In this way, the light-emitting module 101 according to the present embodiment is manufactured.

FIG. 27 is a schematic cross-sectional view illustrating a light-emitting module according to the fifth embodiment.

As illustrated in FIG. 27, in the light-emitting module 101 according to the present embodiment, the plurality of light-emitting elements 30 are provided on the substrate 10, and one lens 80 is provided on each light-emitting element 30. The lens 80 is in contact with the light-emitting element 30. The lens 80 is the first portion 1112 of the photoresist member 1110 described above. Thus, the lens 80 is a convex lens made of material having a light-transmissive property whose chemical stability is improved by exposing the negative type photoresist to light.

In the light-emitting module 101, the light shielding member 50, the light-transmissive member 60, and the wavelength conversion member 70 are not provided. Although the adhesion layer 16, the flattening layer 17, the adhesive layer 18, and the buffer layer 19 are not illustrated, they may be provided or need not be provided. In FIG. 27, an internal structure of the substrate 10 and an internal structure of the light-emitting element 30 are omitted, but the configurations of the substrate 10 and the light-emitting element 30 are the same as or similar to those of the first embodiment. In FIG. 27, an example of optical paths of light emitted from the light-emitting element 30 is indicated by broken lines. The same applies to similar drawings described below.

As illustrated in FIG. 27, according to the present embodiment, the light emitted from the light extraction surface 30S of each light-emitting element 30 is incident on the lens 80 arranged immediately above the light extraction surface 30S, and is condensed by the lens 80. Accordingly, most of the light emitted from the light-emitting element 30 is directed upward, and thus the intensity of light emitted on the optical axis (immediately above) of the light-emitting module 101 improves.

According to the present embodiment, the lens 80 can be formed immediately above each light-emitting element 30 in a self-aligned manner. This results in high positional accuracy and high shape accuracy of the lens 80, and can also reduce the manufacturing cost of the light-emitting module 101. The configurations, method for manufacturing, operation, and effects of the present embodiment other than those described above are the same as or similar to those of the first embodiment.

### Sixth Embodiment

The present embodiment is different from the fifth embodiment in that the light shielding member 50 is provided.

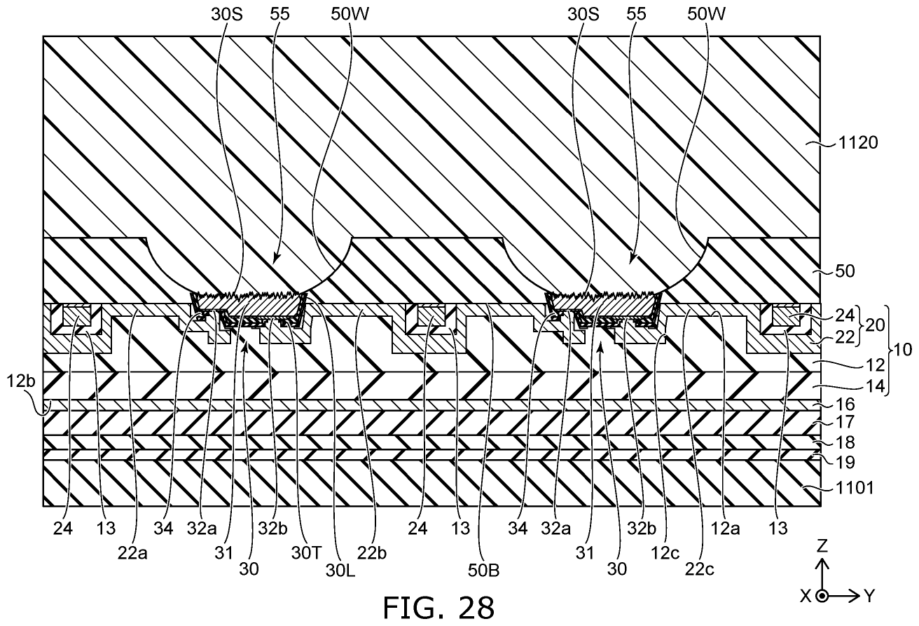

FIGS. 28 to 30 are schematic cross-sectional views, each illustrating a step of a method for manufacturing a light-emitting module according to a sixth embodiment.

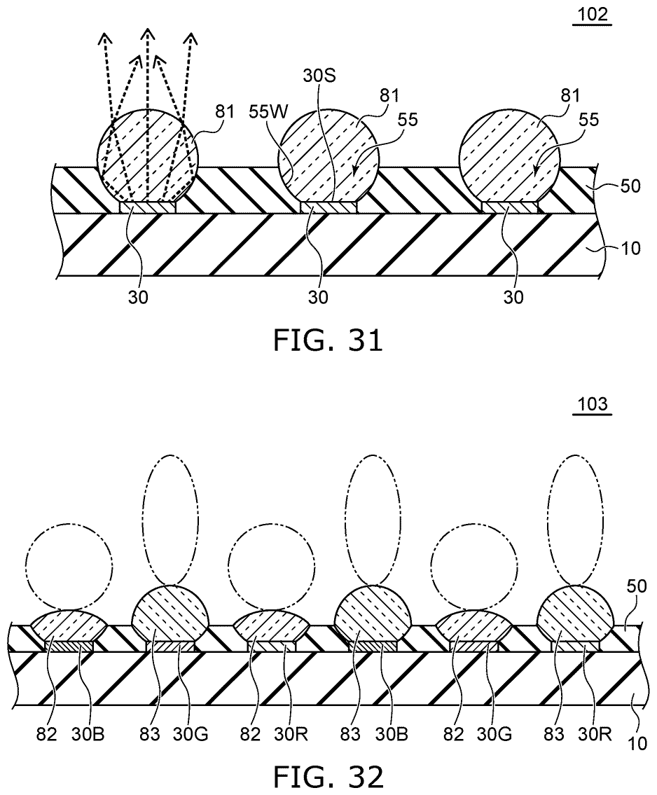

FIG. 31 is a schematic cross-sectional view illustrating a light-emitting module according to the sixth embodiment.

In the method for manufacturing a light-emitting module according to the present embodiment, first, the steps illustrated in FIGS. 3 to 8 are performed. Subsequently, as illustrated in FIG. 28, a photoresist member 1120 made of negative type photoresist is arranged on the light shielding member 50 and on the light-emitting elements 30. The photoresist member 1120 is also arranged in the recessed portions 55 of the light shielding member 50.

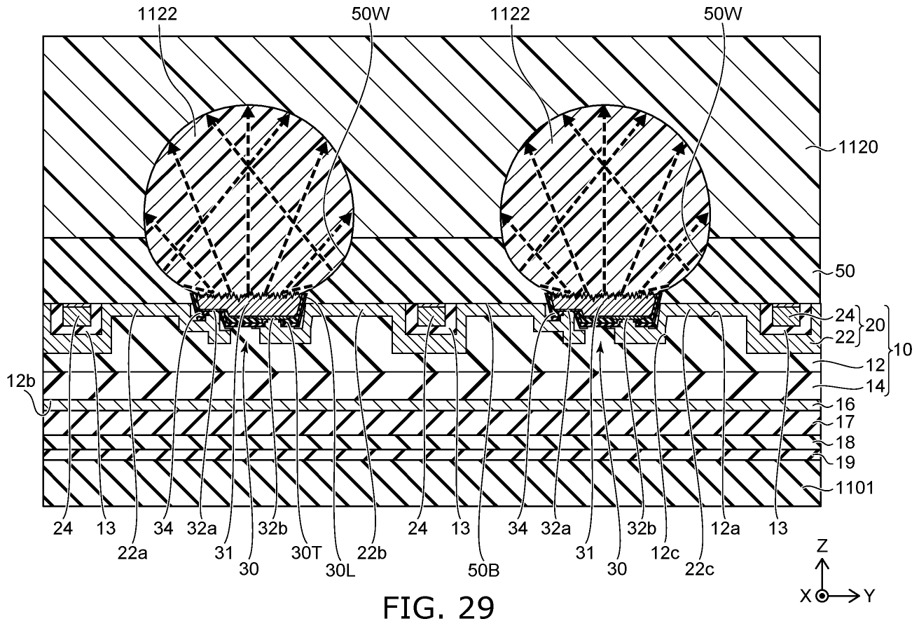

As illustrated in FIG. 29, electric power is supplied to the light-emitting elements 30 via the wiring layer 20, and the light-emitting elements 30 are lit. Accordingly, the light emitted from the light-emitting element 30 travels in the photoresist member 1120, and exposes each portion of the photoresist member 1120 to the light. Part of the light emitted from the light-emitting element 30 is reflected by the inner wall surface 50W of the light shielding member 50 and travels in the photoresist member 1120. As a result, the light-exposure amount becomes a threshold value or more in a second portion 1122 of the photoresist member 1120 located in the vicinity of the light-emitting element 30.

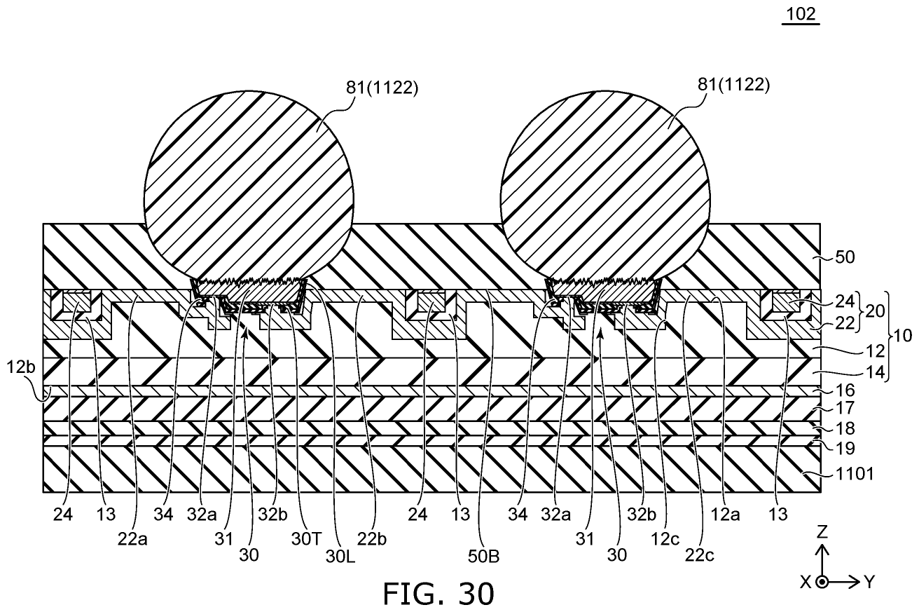

Subsequently, as illustrated in FIG. 30, the photoresist member 1120 is developed. Accordingly, the second portions 1122 of the photoresist member 1120 remain, and the other portions are removed. As a result, each of the second portions 1122 of the photoresist member 1120 becomes the lens 81. In this way, a light-emitting module 102 according to the present embodiment is manufactured.

As illustrated in FIG. 31, in the light-emitting module 102 according to the present embodiment, the plurality of light-emitting elements 30 and the light shielding member 50 are arranged on the substrate 10. The recessed portion 55 is formed immediately above the light-emitting element 30 in the light shielding member 50. The lens 81 is disposed immediately above the light-emitting element 30 on the light shielding member 50.

A lower portion of the lens 81 is arranged in the light shielding member 50, and is in contact with the light extraction surface 30S of the light-emitting element 30 and the inner wall surface 50W of the light shielding member 50. Thus, a shape of the lower portion of the lens 81 corresponds to a shape of the light extraction surface 30S of the light-emitting element 30 and the inner wall surface 50W of the light shielding member 50. In the step illustrated in FIG. 29, part of the light emitted from the light-emitting element 30 travels in the photoresist member 1120 after having being reflected by the inner wall surface 50W of the light shielding member 50. Thus, a shape of an upper portion of the lens 81, that is, a shape of a portion of the lens 81 located higher position than the light shielding member 50 does not necessarily match the light distribution characteristics of the light-emitting element 30 itself.

According to the present embodiment, by combining the light shielding member 50 and the lens 81, the light distribution characteristics of the light emitted from the light-emitting element 30 can be controlled with a high degree of freedom. The configurations, method for manufacturing, operation, and effects of the present embodiment other than those described above are the same as or similar to those of the fifth embodiment.

In the present embodiment, as the plurality of light-emitting elements 30, a single type of light-emitting elements that emit light of the same color may be provided, but multiple types of light-emitting elements that emit light of different colors may be provided. For example, a set of three light-emitting elements, including a light-emitting element that emits red light, a light-emitting element that emits green light, and a light-emitting element that emits blue light, may be provided. Accordingly, full-color illumination or display can be implemented.

In this case, for the material of the photoresist member 1120, a resist material that is sensitive to all of red light, green light, and blue light is used. When there is a variation in photosensitivity depending on the color of light, adjusting the light emission amount in the light exposure step illustrated in FIG. 29 allows the lens 81 to have a uniform size. For example, when the photoresist member 1120 is likely to be sensitive to blue light, and is less likely to be sensitive to red light, the light emission amount of blue light is reduced relative to the light emission amount of red light in the light exposure step illustrated in FIG. 29. Examples of a method of reducing the light emission amount include reducing the intensity of light and/or shortening the light emission time.

### Seventh Embodiment

The present embodiment is different from the sixth embodiment in that two types of lenses are provided.

FIG. 32 is a schematic cross-sectional view illustrating a light-emitting module according to a seventh embodiment.

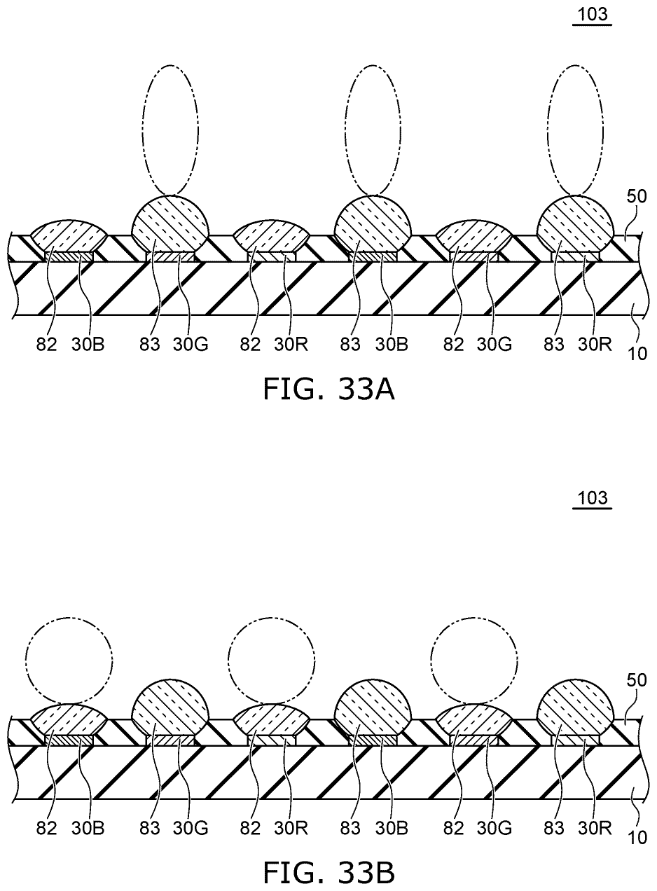

FIGS. 33A and 33B are schematic cross-sectional views, each illustrating an operation of the light-emitting module according to the seventh embodiment. In FIGS. 32, 33A and 33B, the light distribution characteristics of the light after having passed through the lens are indicated by a two-dot chain line.

As illustrated in FIG. 32, in a light-emitting module 103 according to the present embodiment, a plurality of light-emitting units are arranged, and as light-emitting elements in each of the light-emitting units, one light-emitting element 30R that emits red light, one light-emitting element 30G that emits green light, and one light-emitting element 30B that emits blue light are provided. The number of light-emitting elements constituting each light-emitting unit is not limited to three, and may be two or four or more. The combination of colors of light is not limited to red, green, and blue.

In the light-emitting module 103, two types of lenses 82 and 83 are provided. The lens 82 is thinner than the lens 83, and the focal length of the lens 82 is greater than the focal length of the lens 83. One lens 82 is arranged on each of some of the light-emitting elements 30R, and one lens 83 is arranged on each of the other light-emitting elements 30R. The same applies to the light-emitting elements 30G and 30B. The light distribution characteristic of the light having passed through the lens 82 is wider than the light distribution characteristic of the light having passed through the lens 83.

The lenses 82 and 83 are separately formed by using different light emission amounts between the light-emitting elements in the step illustrated in FIG. 29. When the lens 82 is formed, the light-emitting element arranged immediately below the lens 82 is lit with a first light emission amount. When the lens 83 is formed, the light-emitting element arranged immediately below the lens 83 is lit with a second light emission amount larger than the first light emission amount. As described above, when there is a variation in the photosensitivity of the photoresist member depending on the color of light, adjusting the first light emission amount depending on the color of light allows the lens 82 to have a uniform size and shape, and adjusting the second light emission amount depending on the color of light allows the lens 83 to have a uniform size and shape.

The light-emitting module 103 according to the present embodiment may be combined with a liquid crystal module to form an image display device as illustrated in FIG. 9, or may form an image display device in which the light-emitting elements themselves are used as pixels as illustrated in FIG. 23. These image display devices may be, for example, displays of laptop personal computers, stationary displays, or in-vehicle displays described later in a tenth embodiment.

Next, the operation of the light-emitting module 103 according to the present embodiment is described.

The light-emitting module 103 can implement a narrow field of view mode, a wide field of view mode, and a full lighting mode.

As illustrated in FIG. 33A, in the narrow field of view mode, the light-emitting elements 30R, 30G, and 30B, each of which is arranged immediately below the lens 83, are lit, and the light-emitting elements 30R, 30G, and 30B, each of which is arranged immediately below the lens 82, are turned off. Accordingly, the light distribution characteristics of each light-emitting element are narrowed. As a result, in the image display device including the light-emitting module 103, the angle at which an image can be visually recognized is narrowed. For example, when privacy is important in the laptop personal computer or when information needs to be provided only to a driver on the in-vehicle display, the narrow field of view mode is preferable.

As illustrated in FIG. 33B, in the wide field of view mode, the light-emitting elements 30R, 30G, and 30B, each of which is arranged immediately below the lens 82, are lit, and the light-emitting elements 30R, 30G, and 30B, each of which is arranged immediately below the lens 83, are turned off. Accordingly, the light distribution characteristics of each light-emitting element are widened. As a result, in the image display device including the light-emitting module 103, the angle at which the image can be visually recognized is widened. For example, when a plurality of persons view the same screen on the laptop personal computer or when information is provided not only to a driver but also to an occupant on the passenger seat on the in-vehicle display, the wide field of view mode is preferable.

As illustrated in FIG. 32, in the full lighting mode, the light-emitting elements 30R, 30G, and 30B arranged immediately below the lenses 82, and the light-emitting elements 30R, 30G, and 30B arranged immediately below the lenses 83, are lit. Accordingly, the intensity of light of the light-emitting module 103 increases, and in the image display device including the light-emitting module 103, an image can be brightened. For example, when visual recognition of the image is difficult due to the surroundings that are too bright, such as when the image display device is used in a place exposed to direct sunlight, the full lighting mode is preferable. The configurations, method for manufacturing, operation, and effects of the present embodiment other than those described above are the same as or similar to those of the sixth embodiment.

### Eighth Embodiment

The present embodiment is different from the seventh embodiment in that lenses are arranged immediately above only some of the light-emitting elements.

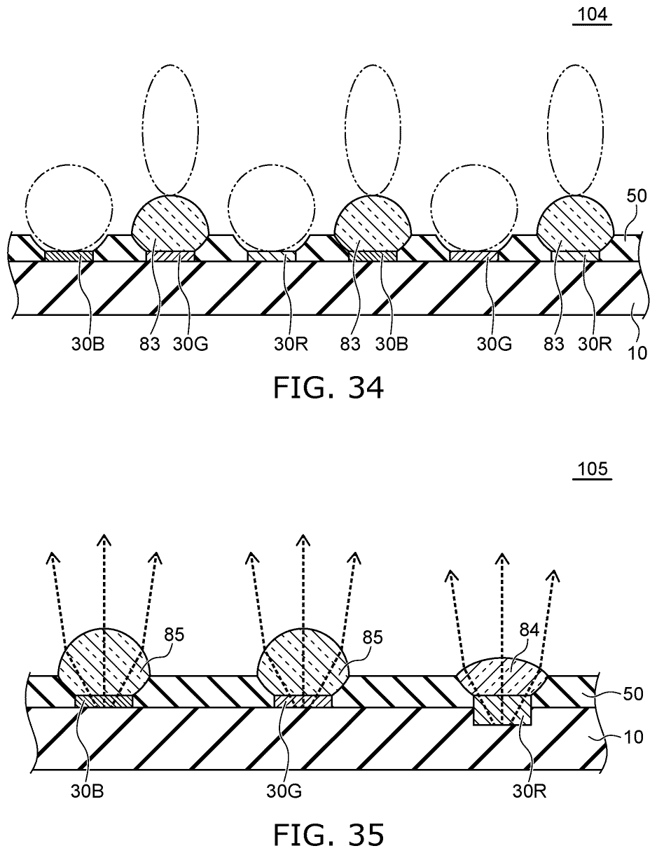

FIG. 34 is a schematic cross-sectional view illustrating a light-emitting module according to an eighth embodiment.

As illustrated in FIG. 34, a light-emitting module 104 according to the present embodiment is different from the light-emitting module 103 according to the seventh embodiment in that the lenses 82 are not provided. That is, some of the light-emitting elements are not provided with a lens immediately above them, and light emitted from the light-emitting elements is emitted from the light-emitting module 104 directly or after being reflected by the light shielding member 50. The light distribution characteristics of the light emitted without being transmitted through the lens are wider than the light distribution characteristics of the light emitted after being transmitted through the lens 83.

According to the present embodiment, the narrow field of view mode, the wide field of view mode, and the full lighting mode can also be implemented similarly to the seventh embodiment. The configurations, method for manufacturing, operation, and effects of the present embodiment other than those described above are the same as or similar to those of the seventh embodiment.

### Ninth Embodiment

The present embodiment is an example in which the light distribution characteristics become more uniform by using different lens thicknesses when the thicknesses of the light-emitting elements are different from each other.

FIG. 35 is a schematic cross-sectional view illustrating a light-emitting module according to a ninth embodiment.

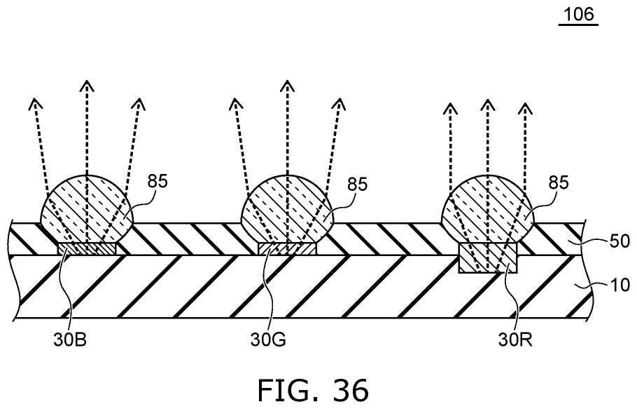

FIG. 36 is a schematic cross-sectional view illustrating a light-emitting module according to a reference example.

As illustrated in FIG. 35, in a light-emitting module 105 according to the present embodiment, the thickness of the light-emitting element 30R that emits red light is larger than the thickness of the light-emitting element 30G that emits green light and the thickness of the light-emitting element 30B that emits blue light. In the example, the thickness of the light-emitting element 30R is 150 μm, and the thickness of the light-emitting element 30G and the thickness of the light-emitting element 30B are both 120 μm.

In the light-emitting module 105, a lens 84 is arranged immediately above the light-emitting element 30R, and lenses 85 are arranged immediately above the light-emitting element 30G and the light-emitting element 30B. Red light emitted from the light-emitting element 30R is incident on the lens 84. Green light emitted from the light-emitting element 30G is incident on the lens 85 arranged immediately above the light-emitting element 30G. Blue light emitted from the light-emitting element 30B is incident on the lens 85 arranged immediately above the light-emitting element 30B. The lens 84 is thinner than the lens 85, and the focal length of the lens 84 is greater than the focal length of the lens 85.

In each light-emitting element, an n-type semiconductor layer, a light-emitting layer, and a p-type semiconductor layer are layered in order from the lower portion, that is, the substrate 10 side, and the p-type semiconductor layer is thicker than the n-type semiconductor layer and the light-emitting layer. Thus, the light-emitting layer is located in a portion of the light-emitting element on the substrate 10 side. Thus, a distance from the light-emitting layer of the light-emitting element 30R to the upper surface of the light-emitting element 30R is longer than a distance from the light-emitting layer of the light-emitting element 30G to the upper surface of the light-emitting element 30G, and longer than a distance from the light-emitting layer of the light-emitting element 30B to the upper surface of the light-emitting element 30B.

As illustrated in FIG. 36, in a light-emitting module 106 according to the reference example, identical lenses 85 are arranged on all the light-emitting elements. In this case, an optical path length from the light-emitting layer of the light-emitting element 30R to the lens surface of the lens 85 is greater than an optical path length from the light-emitting layer of the light-emitting element 30G to the lens surface of the lens 85, and greater than an optical path length from the light-emitting layer of the light-emitting element 30B to the lens surface of the lens 85. The greater the optical path length to the lens surface, the more the light flux is narrowed, which improves the light-condensing property. Thus, the light distribution characteristics of the light emitted from the light-emitting element 30R and transmitted through the lens 85 are narrower than the light distribution characteristics of the light emitted from the light-emitting element 30G or 30B and transmitted through the lens 85. As a result, color shift occurs in which the color of light varies depending on the angle at which an image is visually recognized.

In view of this, in the present embodiment, as illustrated in FIG. 35, the focal length of the lens 84 arranged immediately above the light-emitting element 30R is increased relative to the focal length of the lens 85 arranged immediately above the light-emitting elements 30G and 30B. Accordingly, the light distribution characteristics of the light emitted from the light-emitting element 30R and transmitted through the lens 84 are comparable with the light distribution characteristics of the light emitted from the light-emitting element 30G or 30B and transmitted through the lens 85. As a result, the light distribution characteristics can become more uniform between the light-emitting elements, and the color shift due to the angle at which an image is visually recognized can be reduced. The configurations, method for manufacturing, operation, and effects of the present embodiment other than those described above are the same as or similar to those of the sixth embodiment.

### Tenth Embodiment

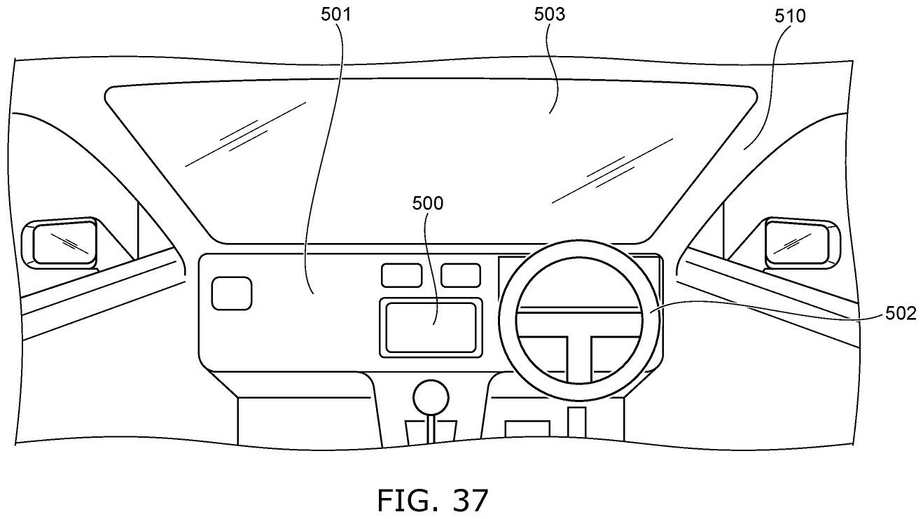

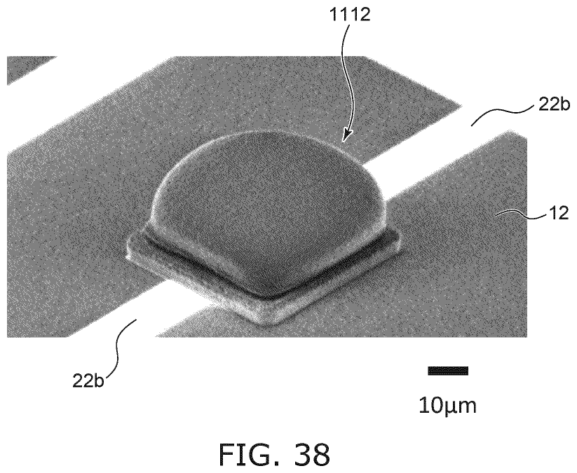

FIG. 37 is a schematic top view illustrating an image display device according to a tenth embodiment.

FIG. 37 illustrates an image display device 500 and the inside of a vehicle 510 in which the image display device 500 is installed.

As illustrated in FIG. 37, the image display device 500 is installed substantially at the center of a dashboard 501 arranged in the vehicle 510. A windshield 503 is arranged in front of the dashboard 501, and a driver's seat and a steering wheel 502 are arranged on the right side of the dashboard 501. A passenger seat is disposed on the left side of the dashboard 501. The image display device 500 is installed substantially at the center of the dashboard 501 between the driver's seat and the passenger seat, and is arranged at a position where the occupants on the driver's seat and the passenger seat can view the image display device at the same time.

The image display device 500 may be, for example, the image display device 1 including the light-emitting module 100 and the liquid crystal module 2 that are illustrated in FIG. 9. Alternatively, the image display device 500 may be the image display device 300 illustrated in FIG. 23 or the image display device 400 illustrated in FIG. 25.

The aforementioned light-emitting modules according to the first, second, and fifth to ninth embodiments, and the aforementioned image display devices according to the third and fourth embodiments can be used not only as the in-vehicle image display device illustrated in FIG. 37, but also as various monitors for information processing devices, for various industrial use, for medical use, and the like, and as a monitor for a head mounted display for a game device, and the like.

According to the embodiments described above, the method for manufacturing a light-emitting module with improved accuracy of forming the light shielding member, the method for manufacturing an image display device, and the light-emitting module can be provided.

### Test Example

In the present test example, the method for manufacturing a light-emitting module according to the first embodiment described above was performed, and the first portion 1112 of the photoresist member 1110, which is the intermediate structure of the light-emitting module, was observed with a scanning electron microscope (SEM).

FIG. 38 is an SEM photograph showing the first portion of the photoresist member fabricated in the present test example. The imaging range of FIG. 38 corresponds to the schematic perspective view illustrated in FIG. 6. As illustrated in FIG. 38, the first portion 1112 fabricated in the present test example had a substantially rectangular parallelepiped shape with rounded vertices and sides.

While several embodiments of the present invention have been described above, these embodiments have been presented by way of example and are not intended to limit the scope of the invention. These novel embodiments may be implemented in various other forms and various omissions, substitutions, and changes may be made without departing from the spirit of the invention. These embodiments and variations thereof are included in the scope and spirit of the invention and are within the scope of the invention described in the claims and equivalents thereof. The aforementioned embodiments can be implemented in combination with each other.

Embodiments include the following clauses.

### Clause 1

A method for manufacturing a light-emitting module, the method comprising:
preparing a first intermediate member comprising:
   a support member having a first surface and a second surface opposite the first surface,
   a wiring layer at least partially located on the first surface,
   a plurality of light-emitting elements, each of which is arranged on a first surface side of the support member, has a light extraction surface through which light is emitted along a direction from the second surface to the first surface, and is electrically connected to the wiring layer, and
   a first photoresist member integrally covering the plurality of light-emitting elements; and
forming a second intermediate member in which a plurality of first portions of the first photoresist member according to an arrangement of the plurality of light-emitting elements have been sensitized to light emitted from the plurality of light-emitting elements by supplying a current to the plurality of light-emitting elements via the wiring layer.

### Clause 2

The method for manufacturing a light-emitting module according to clause 1, wherein:
the first photoresist member is a negative type photoresist member; and
the method further comprises:
removing a portion of the first photoresist member other than the plurality of first portions of the second intermediate member while leaving the plurality of first portions;
arranging a light shielding member in a region where the other portion of the first photoresist member has been removed; and
removing the plurality of first portions.

### Clause 3

The method for manufacturing a light-emitting module according to clause 2, further comprising:
after the removing of the plurality of first portions, arranging a light-transmissive member on the plurality of light-emitting elements.

### Clause 4

The method for manufacturing a light-emitting module according to clause 3, further comprising:
arranging a wavelength conversion member on the light-transmissive member.

### Clause 5

The method for manufacturing a light-emitting module according to clause 2, further comprising:
arranging a wavelength conversion member on the light shielding member such that a space is located between the wavelength conversion member and the plurality of light-emitting elements after the removing of the plurality of first portions.

### Clause 6

The method for manufacturing a light-emitting module according to clause 2, further comprising:
after the removing of the plurality of first portions, arranging a second photoresist member that is a negative type photoresist member on the plurality of light-emitting elements and on the light shielding member;
sensitizing to light a plurality of second portions of the second photoresist member according to an arrangement of the plurality of light-emitting elements by lighting at least some of the plurality of light-emitting elements by supplying a current to the plurality of light-emitting elements via the wiring layer; and
removing a remainder of the second photoresist member while leaving the plurality of second portions of the second photoresist member.

### Clause 7

The method for manufacturing a light-emitting module according to clause 6, wherein:
in the sensitizing, some of the light-emitting elements are lit with a first light emission amount, and others of the light-emitting elements are lit with a second light emission amount larger than the first light emission amount.

### Clause 8

The method for manufacturing a light-emitting module according to clause 6, wherein
in the sensitizing, some of the light-emitting elements are lit, and others of the light-emitting elements are not lit.

### Clause 9

The method for manufacturing a light-emitting module according to any of clauses 6-9, wherein:
the plurality of light-emitting elements comprise:
   a first light-emitting element configured to emit light of a first color, and
   a second light-emitting element configured to emit light of a second color different from the first color, a thickness of the second light-emitting element being larger than a thickness of the first light-emitting element, and
at least one of the second portions on which the light of the first color is incident is thicker than at least one of the second portions on which the light of the second color is incident.

### Clause 10

The method for manufacturing a light-emitting module according to clause 1, wherein:
the first photoresist member is a negative type photoresist member; and
the method further comprises:
removing a portion of the first photoresist member other than the plurality of first portions of the second intermediate member while leaving the plurality of first portions of the second intermediate member.

### Clause 11

The method for manufacturing a light-emitting module according to clause 1, wherein
the first photoresist member is a positive type photoresist member; and
the method further comprises:
removing the plurality of first portions of the second intermediate member.

### Clause 12

The method for manufacturing a light-emitting module according to clause 11, wherein:
the first photoresist member comprises at least one of a light scattering member or a light absorbing member.

### Clause 13

The method for manufacturing a light-emitting module according to any of clauses 2-12, wherein:
the first photoresist member is a chemically amplified type photoresist member; and
the forming of the second intermediate member comprises, after exposing the plurality of first portions to light, subjecting the second intermediate member to heat treatment.

### Clause 14

The method for manufacturing a light-emitting module according to any of clauses 1-13, wherein:
in a plan view, an outer peripheral shape of each of the plurality of first portions is any one of a circle, an ellipse, or a polygon with rounded corner portions.

### Clause 15

A method for manufacturing an image display device, the method comprising
incorporating a light-emitting module manufactured by the method for manufacturing a light-emitting module according to any of clauses 1-14 into a liquid crystal module.

### Clause 16

A light-emitting module comprising:
a substrate comprising:
   a support member having an upper surface, and
   a wiring layer;
a plurality of light-emitting elements, each of which is arranged on an upper surface side of the substrate, has a light extraction surface through which light is emitted upward from the substrate, and is electrically connected to the wiring layer; and
a light shielding member containing a photosensitizer and arranged around each of the plurality of light-emitting elements in a top view; wherein:
the light-emitting module comprises a recessed portion opened upward at a position corresponding to each of the plurality of light-emitting elements, each recessed portion being defined by the light extraction surface of a respective light-emitting element and a lateral surface of the light shielding member.

### Clause 17

The light-emitting module according to clause 16, further comprising:
a plurality of lenses, each of which is arranged on a corresponding one of the plurality of light-emitting elements, wherein a lower portion of each lens is located in the recessed portion.

### Clause 18

The light-emitting module according to clause 17, wherein:
the plurality of lenses include:
   one or more first lenses located immediately above one or more respective first light-emitting elements of the light-emitting elements, and
   one or more second lenses located immediately above one or more respective second light-emitting element of the light-emitting elements, wherein:
   a focal length of each of the one or more first lenses is greater than a focal length of each of the one or more second lenses.

### Clause 19

The light-emitting module according to clause 18, wherein:
the one or more first lenses include a plurality of first lenses, which includes a first lens located above a respective first light-emitting element that is configured to emit light of a first color, and another first lens located above a respective other first light-emitting element that is configured to emit light of a second color different from the first color; and
the one or more second lenses include a plurality of second lenses, which includes a second lens located above a respective second light-emitting element that is configured to emit light of the first color, and another second lens located above a respective other second light-emitting element that is configured to emit light of the second color different from the first color.

### Clause 20

The light-emitting module according to clause 18, wherein:
the one or more first light-emitting elements are configured to emit light of a first color, and the one or more second light-emitting elements are configured to emit light of a second color different from the first color, and
a thickness of the first light-emitting element is larger than a thickness of the second light-emitting element.

### REFERENCE CHARACTER LIST

1, 300, 400, 500 Image display device, 10, 210, 310, 410 Substrate, 12, 212, 312, 412 Support member, 20, 220, 320, 420 Wiring layer, 30 30R, 30G, 30B Light-emitting element, 30S Light extraction surface, 30T Electrode formation surface, 50, 250 Light shielding member, 50E1, 50E2, 250E1, 250E2 Edge portion, 50W, 250W Inner wall surface, 55, 255 Recessed portion, 60, 460 Light-transmissive member, 70, 470a, 470b, 470c Wavelength conversion member, 72 Base material, 74, 474a, 474b, 474c Wavelength conversion substance, 80, 81, 82, 83, 84, 85 Lens, 100, 101, 102, 103, 104, 105, 106, 200 Light-emitting module, 382, 482 Current signal drive circuit, 384, 484. Row selection drive circuit, 486 Drive circuit, 1100, 1100a, 1100c, 1200, 1200a, 1200b, 1200c, 1200d, 1200e Intermediate member, 1110, 1120, 1210, 1350 Photoresist member, 1112, 1112a, 1212a, 1352 First portion, 1122 Second portion

What is claimed is:

1. A method for manufacturing a light-emitting module, the method comprising:
preparing a first intermediate member comprising:
a support member having a first surface and a second surface opposite the first surface,
a wiring layer at least partially located on the first surface,
a plurality of light-emitting elements, each of which is arranged on a first surface side of the support member, has a light extraction surface through which light is emitted along a direction from the second surface to the first surface, and is electrically connected to the wiring layer, and
a first photoresist member integrally covering the plurality of light-emitting elements; and
forming a second intermediate member in which a plurality of first portions of the first photoresist member according to an arrangement of the plurality of light-emitting elements have been sensitized to light emitted from the plurality of light-emitting elements by supplying a current to the plurality of light-emitting elements via the wiring layer.

2. The method for manufacturing a light-emitting module according to claim 1, wherein:
the first photoresist member is a negative type photoresist member; and
the method further comprises:
removing a portion of the first photoresist member other than the plurality of first portions of the second intermediate member while leaving the plurality of first portions;
arranging a light shielding member in a region where the other portion of the first photoresist member has been removed; and
removing the plurality of first portions.

3. The method for manufacturing a light-emitting module according to claim 2, further comprising:
after the removing of the plurality of first portions, arranging a light-transmissive member on the plurality of light-emitting elements.

4. The method for manufacturing a light-emitting module according to claim 3, further comprising:
arranging a wavelength conversion member on the light-transmissive member.

5. The method for manufacturing a light-emitting module according to claim 2, further comprising:
arranging a wavelength conversion member on the light shielding member such that a space is located between the wavelength conversion member and the plurality of light-emitting elements after the removing of the plurality of first portions.

6. The method for manufacturing a light-emitting module according to claim 2, further comprising:
after the removing of the plurality of first portions, arranging a second photoresist member that is a negative type photoresist member on the plurality of light-emitting elements and on the light shielding member;
sensitizing to light a plurality of second portions of the second photoresist member according to an arrangement of the plurality of light-emitting elements by lighting at least some of the plurality of light-emitting elements by supplying a current to the plurality of light-emitting elements via the wiring layer; and
removing a remainder of the second photoresist member while leaving the plurality of second portions of the second photoresist member.

7. The method for manufacturing a light-emitting module according to claim 6, wherein:
in the sensitizing, some of the light-emitting elements are lit with a first light emission amount, and others of the light-emitting elements are lit with a second light emission amount larger than the first light emission amount.

8. The method for manufacturing a light-emitting module according to claim 6, wherein
in the sensitizing, some of the light-emitting elements are lit, and others of the light-emitting elements are not lit.

9. The method for manufacturing a light-emitting module according to claim 6, wherein:
the plurality of light-emitting elements comprise:
a first light-emitting element configured to emit light of a first color, and
a second light-emitting element configured to emit light of a second color different from the first color, a thickness of the second light-emitting element being larger than a thickness of the first light-emitting element, and
at least one of the second portions on which the light of the first color is incident is thicker than at least one of the second portions on which the light of the second color is incident.

10. The method for manufacturing a light-emitting module according to claim 1, wherein:
the first photoresist member is a negative type photoresist member; and
the method further comprises:
removing a portion of the first photoresist member other than the plurality of first portions of the second intermediate member while leaving the plurality of first portions of the second intermediate member.

11. The method for manufacturing a light-emitting module according to claim 1, wherein
the first photoresist member is a positive type photoresist member; and
the method further comprises:
removing the plurality of first portions of the second intermediate member.

12. The method for manufacturing a light-emitting module according to claim 11, wherein:
the first photoresist member comprises at least one of a light scattering member or a light absorbing member.

13. The method for manufacturing a light-emitting module according to claim 2, wherein:
the first photoresist member is a chemically amplified type photoresist member; and
the forming of the second intermediate member comprises, after exposing the plurality of first portions to light, subjecting the second intermediate member to heat treatment.

14. The method for manufacturing a light-emitting module according to claim 1, wherein:
in a plan view, an outer peripheral shape of each of the plurality of first portions is any one of a circle, an ellipse, or a polygon with rounded corner portions.

15. A method for manufacturing an image display device, the method comprising
incorporating a light-emitting module manufactured by the method for manufacturing a light-emitting module according to claim 1 into a liquid crystal module.

16. A light-emitting module comprising:
a substrate comprising:
a support member having an upper surface, and
a wiring layer;
a plurality of light-emitting elements, each of which is arranged on an upper surface side of the substrate, has a light extraction surface through which light is emitted upward from the substrate, and is electrically connected to the wiring layer; and
a light shielding member containing a photosensitizer and arranged around each of the plurality of light-emitting elements in a top view; wherein:
the light-emitting module comprises a recessed portion opened upward at a position corresponding to each of the plurality of light-emitting elements, each recessed portion being defined by the light extraction surface of a respective light-emitting element and a lateral surface of the light shielding member.

17. The light-emitting module according to claim 16, further comprising:
a plurality of lenses, each of which is arranged on a corresponding one of the plurality of light-emitting elements, wherein a lower portion of each lens is located in the recessed portion.

18. The light-emitting module according to claim 17, wherein:
the plurality of lenses include:
one or more first lenses located immediately above one or more respective first light-emitting elements of the light-emitting elements, and
one or more second lenses located immediately above one or more respective second light-emitting element of the light-emitting elements, wherein:
a focal length of each of the one or more first lenses is greater than a focal length of each of the one or more second lenses.

19. The light-emitting module according to claim 18, wherein:
the one or more first lenses include a plurality of first lenses, which includes a first lens located above a respective first light-emitting element that is configured to emit light of a first color, and another first lens located above a respective other first light-emitting element that is configured to emit light of a second color different from the first color; and
the one or more second lenses include a plurality of second lenses, which includes a second lens located above a respective second light-emitting element that is configured to emit light of the first color, and another second lens located above a respective other second light-emitting element that is configured to emit light of the second color different from the first color.

20. The light-emitting module according to claim 18, wherein:
the one or more first light-emitting elements are configured to emit light of a first color, and the one or more second light-emitting elements are configured to emit light of a second color different from the first color, and
a thickness of the first light-emitting element is larger than a thickness of the second light-emitting element.
